(19) United States
(12) Patent Application Publication
(10) Pub. No.: US 2016/0079125 A1
(43) Pub. Date: Mar. 17, 2016

(54) SEMICONDUCTOR DEVICES AND METHODS OF MANUFACTURING THE SAME

(71) Applicant: SAMSUNG ELECTRONICS CO., LTD., Suwon-si (KR)

(72) Inventors: Sung-Min KIM, Incheon (KR); Cheol KIM, Hwaseong-si (KR); Dong-Ho CHA, Seongnam-si (KR)

(73) Assignee: SAMSUNG ELECTRONICS CO., LTD., Suwon-si (KR)

(21) Appl. No.: 14/812,137

(22) Filed: Jul. 29, 2015

(30) Foreign Application Priority Data
Sep. 11, 2014 (KR) 10-2014-0120432

(51) Int. Cl. H01L 21/8234; H01L 29/66; H01L 21/306; H01L 21/311

(52) U.S. Cl. CPC H01L 21/823431; H01L 21/823481; H01L 21/823437; H01L 21/31144; H01L 29/66545; H01L 21/30604

(57) ABSTRACT

In a method of manufacturing a semiconductor device, a substrate is etched to form active fins spaced apart from one another in a first direction, and each active fin extends in the first direction. An isolation pattern is formed on the substrate to partially fill a space between the active fins. A mold pattern is formed on the isolation pattern, the mold pattern covering at least a portion of each of the active fins and including an opening exposing a portion of the isolation pattern between the active fins in the first direction. An insulation pattern is formed to fill the opening. The mold pattern is removed to expose the active fins. A gate structure and a dummy structure are formed on the exposed active fins and the insulation pattern, respectively, the gate structure and the dummy structure extending in a second direction substantially perpendicular to the first direction.

### CROSS-REFERENCE TO THE RELATED APPLICATION

This application claims priority from Korean Patent Application No. 10-2014-0120432, filed on Sep. 11, 2014 in the Korean Intellectual Property Office, the contents of which are herein incorporated by reference in their entirety.

### BACKGROUND

1. Field

Methods and apparatuses consistent with example embodiments relate to semiconductor devices including fin-type transistors.

2. Description of the Related Art

As a semiconductor device has a high integration degree, the semiconductor device may include fin-type transistors having three-dimensional (3D) channels. The fin-type transistors of the semiconductor device need to have good electrical characteristics.

### SUMMARY

Example embodiments provide a method of manufacturing a semiconductor device including a fin-type transistor having good electrical characteristics.

Example embodiments also provide a semiconductor device including a fin-type transistor having good electrical characteristics.

According to example embodiments, there is provided a method of manufacturing a semiconductor device. In the method, a substrate may be etched to form a plurality of active fins spaced apart from one another in a first direction, and each active fin may extend in the first direction to a given length. An isolation pattern may be formed on the substrate to partially fill a space between the active fins so that the active fins protrude from an upper surface of the isolation pattern. A mold pattern may be formed on the isolation pattern, the mold pattern covering at least a portion of each of the active fins and including a first opening exposing a portion of the isolation pattern between the active fins in the first direction. An insulation pattern may be formed to fill the first opening. The mold pattern may be removed to form a second opening exposing the active fins. A gate structure and a dummy gate structure may be formed on the exposed active fins and the insulation pattern, respectively, both of the gate structure and the dummy gate structure extending in a second direction substantially perpendicular to the first direction.

In example embodiments, the mold pattern may be formed such that the first opening may be formed to have a sidewall of which a slope is in range of about 80° to about 90°, and a difference between a maximum width in the first direction of the first opening and a minimum width in the first direction of the first opening may be less than about 20% of the maximum width thereof.

In example embodiments, the insulation pattern may be formed such that a difference between a maximum slope of a sidewall of the insulation pattern and a minimum slope of the sidewall thereof may be less than about 20% of the maximum slope thereof.

In example embodiments, the first opening may be formed to extend in the second direction.

In example embodiments, the gate structure may be formed on the isolation pattern and the active fins.

In example embodiments, the first opening may be formed to extend both in the first and second directions, and the mold pattern structure may be formed to have a plurality of mold patterns having an island shape from one another.

In example embodiments, the insulation pattern may be formed to include a first portion extending in the first direction and a second portion extending in the second direction, and the gate structure may be formed on the isolation pattern, the first portion of the insulation pattern and the active fins.

In example embodiments, the mold pattern structure may include a material having a high etching selectivity with respect to the active fins.

In example embodiments, when the mold pattern structure may be formed, a first mold layer may be formed to cover the active fins. A second mold layer may be formed on the first mold layer. The second mold layer may be patterned to form a second mold pattern not overlapping a portion of the isolation pattern between the active fins in the first direction. The first mold layer using the second mold pattern as an etching mask may be etched to form the mold pattern structure including a first mold pattern and the second mold pattern sequentially stacked.

In example embodiments, the first mold layer may include polysilicon, and the second mold layer may include silicon nitride or silicon oxynitride.

In example embodiments, an upper portion of the insulation pattern may be partially etched to control a height of the insulation pattern

In example embodiments, the upper portion of the insulation pattern may be partially etched so that an upper surface of the insulation pattern may be substantially coplanar with or higher than a top surface of each of the active fins.

According to example embodiments, there is provided a method of manufacturing a semiconductor device. The method my include forming a plurality of active fins on a substrate layer to be spaced apart from one another in an active fin direction, forming an insulation pattern to fill an opening between the active fins such that a length of a bottom surface of the insulation pattern facing the substrate layer is substantially equal to a length of the insulation pattern at a height substantially the same as upper surfaces of the active fins, in the active fin direction, and forming a gate structure and a dummy gate structure on the active fins and the insulation pattern, respectively.

In example embodiments, the forming the insulation pattern may be performed by a damascene process so that a sidewall of the insulation pattern has a substantially vertical slope with respect to an upper surface of the substrate layer.

In example embodiments, the substrate layer may be formed of a substrate and an isolation pattern formed on the substrate, and the insulation pattern may be formed on the isolation pattern.

In example embodiments, two or more active fins may be formed to be spaced apart from one another in a direction perpendicular to the active find direction.

In example embodiments, the forming the gate structure may include forming at least one drain region and at least one source region on the active fins at one side and another side of the gate structure, respectively.

According to example embodiments, a method of manufacturing a semiconductor device may include providing a substrate including active fins thereon, the active fins being spaced apart from one another in a first direction and a second direction substantially perpendicular to the first direction, and each of the active fins extending in the first direction, forming an isolation pattern on the substrate, the isolation pattern partially filling a space between the active fins, forming an insulation pattern on the isolation pattern, the insulation pattern enclosing the active fins and including a first portion filling a space between the active fins in the first direction and extending in the second direction and a second portion extending in the first direction to be connected to the first portion, forming a gate structure on the active fins and the second portion of the insulating pattern, the gate structure extending in the second direction, and forming a dummy gate structure on the first portion of the insulation pattern, the dummy gate structure extending in the second direction.

In example embodiments, the insulation pattern is formed such that a difference between a maximum slope of a sidewall of the insulation pattern and a minimum slope of the sidewall of the insulation pattern may be less than about 20% of the maximum slope thereof.

In example embodiments, bottom surfaces of both of the gate structure and dummy gate structure are coplanar on the insulation pattern.

In example embodiments, the insulation pattern may include openings exposing a portion of the active fins so that the insulation pattern may have a grid shape.

In example embodiments, the upper portion of the insulation pattern may be substantially coplanar with or higher than a top surface of each of the active fins.

In example embodiments, the insulation pattern may cover edge portions of the active fins in the first direction.

In example embodiments, the insulation pattern may include a material substantially the same as that of the isolation pattern.

According to example embodiments, there is provided a semiconductor device. The semiconductor device includes a substrate including active fins thereon, the active fins being spaced apart from each other in a first direction and being arranged in a second direction substantially perpendicular to the first direction, and each of the active fins extending in the first direction to a given length, an isolation pattern on the substrate, the isolation pattern partially filling a space between the active fins in the first direction, a side wall of the isolation pattern having a slope in range of about 80° to about 90, a gate structure on the active fins, the gate structure extending in the second direction, and a dummy gate structure on the insulation pattern, the dummy gate structure extending in the second direction.

According to example embodiments, the insulation pattern may have a substantially vertical sidewall and a small difference between slopes of an upper sidewall and a lower sidewall. Also, a decreasing of an effective region of the active pattern due to the insulation pattern may be prevented. The semiconductor device including a fin-type transistor may have good characteristics and a small characteristic variation.

### BRIEF DESCRIPTION OF THE DRAWINGS

Example embodiments will be more clearly understood from the following detailed description taken in conjunction with the accompanying drawings. FIGS. 1 to 50 represent non-limiting, example embodiments as described herein.

FIGS. 1 to 9, 10A, 10B, 11 to 18, 19A and 19B are perspective views and cross cross-sectional views illustrating stages of a method of manufacturing a semiconductor device in accordance with example embodiments;

FIGS. 20 to 31 are perspective views and cross-sectional views illustrating stages of the method of manufacturing a semiconductor device in accordance with example embodiments;

FIGS. 32 to 38, 39A and 39B are perspective views and cross cross-sectional views illustrating stages of a method of manufacturing a semiconductor device in accordance with example embodiments;

FIGS. 40 to 49 are perspective views and cross cross-sectional views illustrating stages of a method of manufacturing a semiconductor device in accordance with example embodiments;

FIG. 50 is a block diagram illustrating an electrical system including a semiconductor device in accordance with example embodiments.

### DETAILED DESCRIPTIONS OF THE EXAMPLE EMBODIMENTS

Various example embodiments of the inventive concept will be described more fully hereinafter with reference to the accompanying drawings. The inventive concept may, however, be embodied in many different forms and should not be construed as limited to the example embodiments set forth herein. Rather, these example embodiments are provided so that this description will be thorough and complete, and will fully convey the scope of the inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

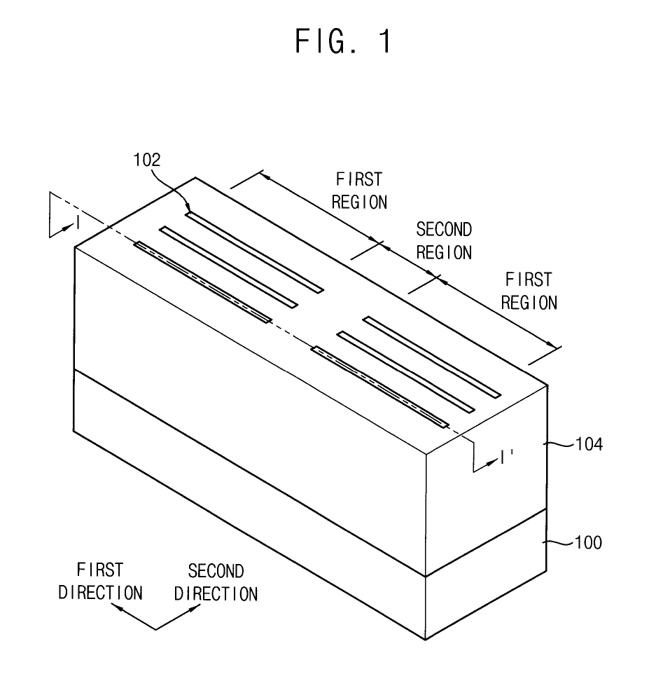

FIGS. 1 to 9, 10A, 10B, 11 to 18, 19A and 19B are perspective views and cross-sectional views illustrating stages of a method of manufacturing a semiconductor device in accordance with example embodiments.

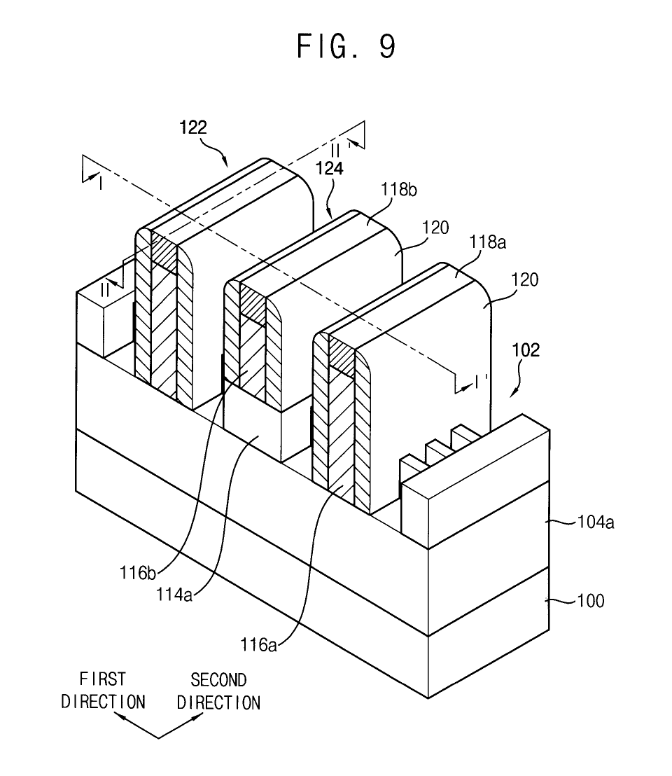

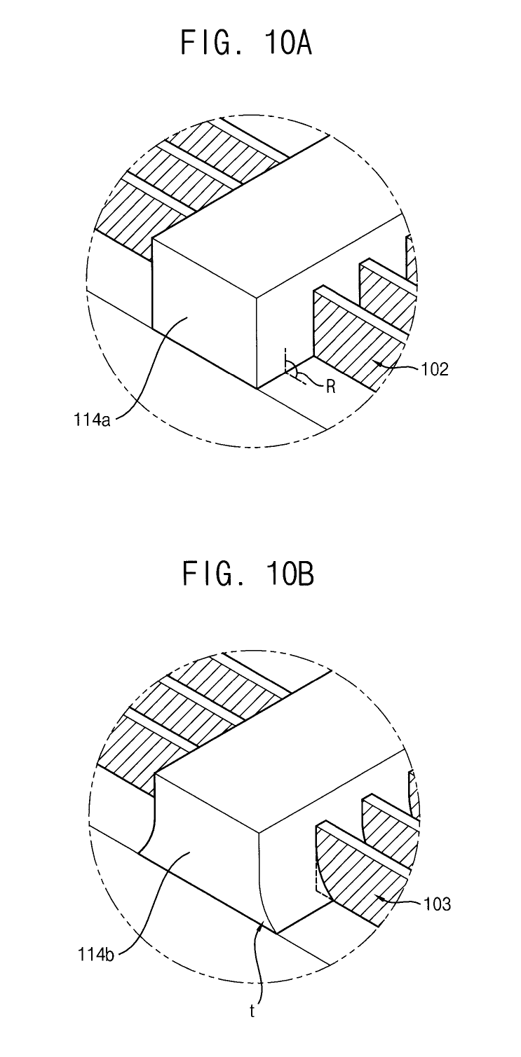

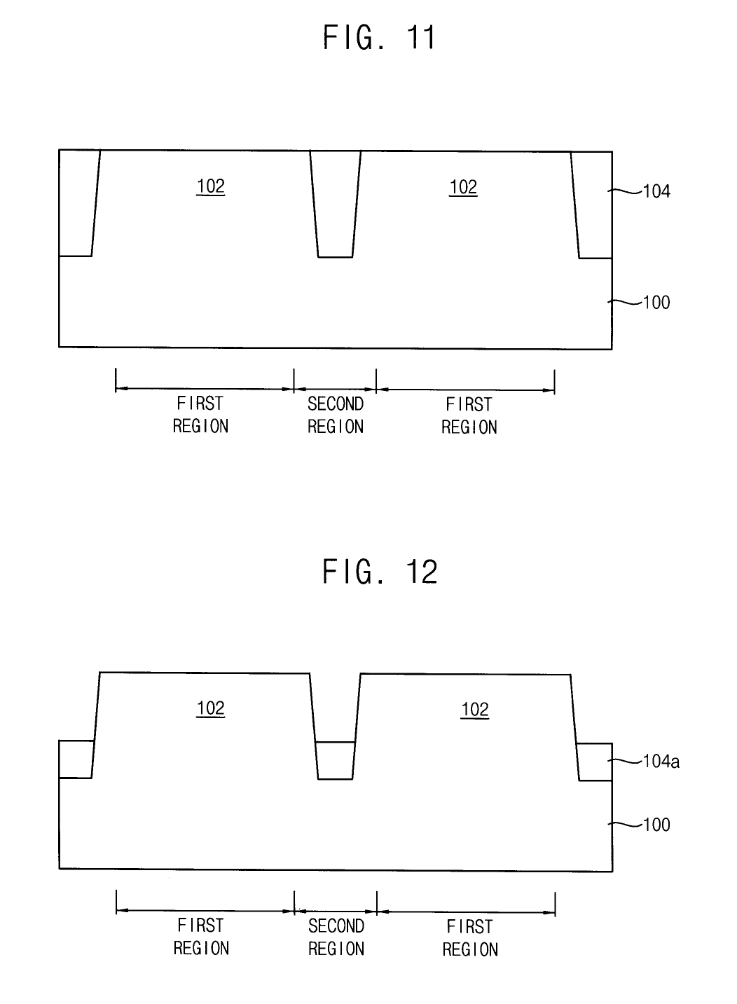

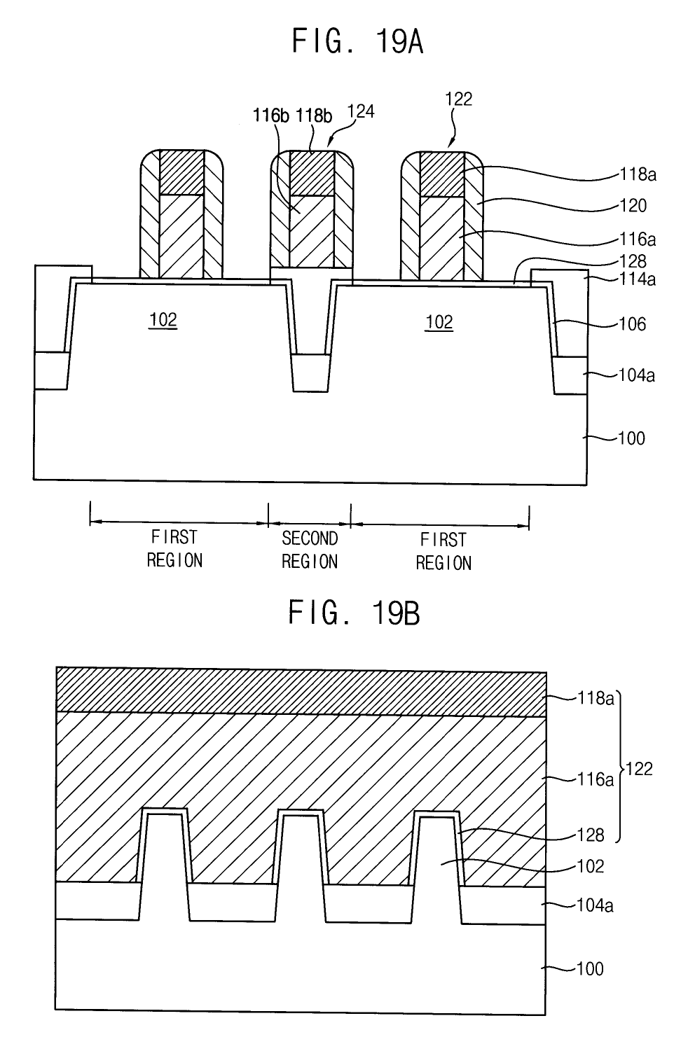

FIGS. 11 to 18 and 19A illustrate cross-sectional views taken along a line I-I′ of FIGS. 1 to 9, respectively, and FIG. 19B illustrates a cross-sectional view taken along a line II-II′ of FIG. 9. FIG. 10A illustrates a portion of an insulation pattern of a semiconductor device in accordance with example embodiments, and FIG. 10B illustrates a portion of an insulation pattern of a related art semiconductor device for comparison with that shown in FIG. 10A.

Referring to FIGS. 1 and 11, an upper portion of a substrate 100 may be partially etched to form active fins 102 and trench (not shown) therebetween. The active fins 102 may include a material substantially the same as that of the substrate 100. A preliminary isolation layer 104 may be formed on the substrate 100 to fill the trench.

The substrate 100 may be a silicon substrate, a germanium substrate, a silicon-germanium substrate, or a III-V compound semiconductor substrate including GaP, GaAs, or GaSb. In some example embodiments, the substrate 100 may include a silicon-on-insulator (SOI) substrate, a germanium-on-insulator (GOI) substrate, etc. The substrate 100 may have a crystalline semiconductor, preferably but not necessarily, a single crystalline semiconductor.

Each of the active fins 102 may extend to a given length in a first direction, and the active fins 102 may be arranged to be spaced apart from one another in the first direction. Also, the active fins 102 may be arranged to be spaced apart from one another in a second direction substantially perpendicular to the first direction.

An insulation layer may be formed on the substrate 100 to sufficiently fill the trench, and may be planarized until top surfaces of the active fins 102 may be exposed to form the preliminary isolation layer 104. The insulation layer may include an oxide, e.g., silicon oxide.

A region of the substrate 100 in which the active fins 102 and first portions of the preliminary isolation layer 104 disposed adjacent thereto in the second direction are formed may be referred to as a first region for forming a fin-type transistor. A region of the substrate 100 in which second portions of the preliminary isolation layer 104 disposed between the active fins 102 in the first direction and third portions of the preliminary isolation layer 104 disposed adjacent to the second portions thereof in the second direction are formed may be referred to as a second region for forming a dummy transistor. Each of the first and second regions may extend in the second direction.

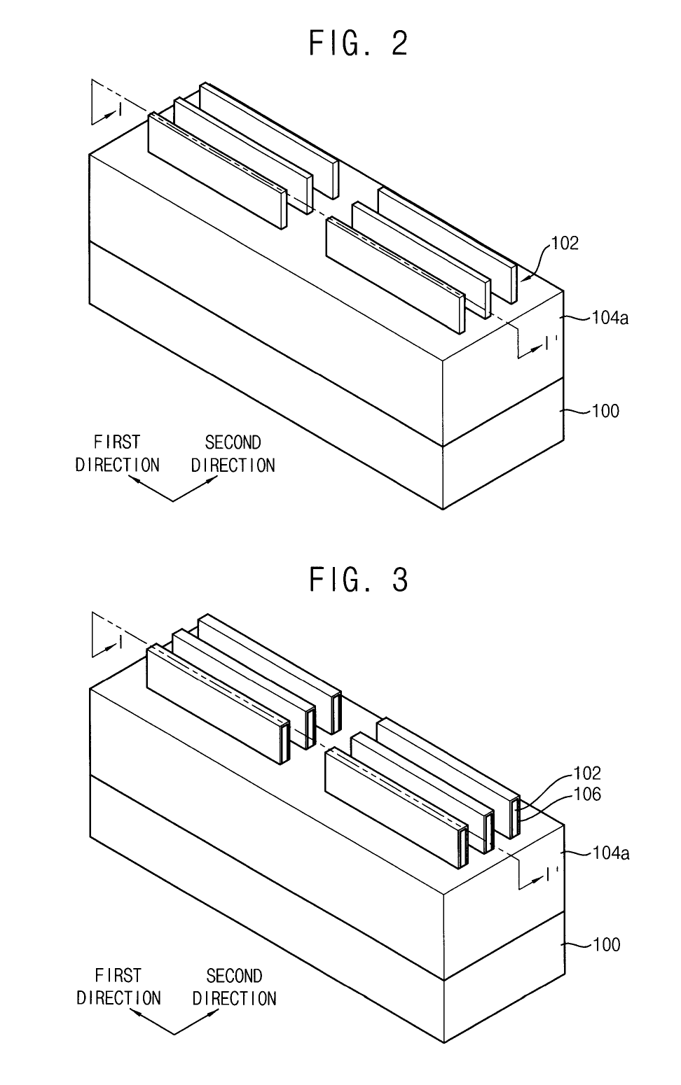

Referring to FIGS. 2 and 12, an upper portion of the preliminary isolation layer 104 may be etched to expose upper sidewalls of the active fins 102, and an isolation pattern 104a filling a lower portion of the trench may be formed. Upper portions of the active fins 102 protruding from an upper surface of the isolation pattern 104a may serve as an effective active region.

In example embodiments, impurities may be lightly doped into the upper portions of the active fins 102 to control a threshold voltage of the fin-type transistor.

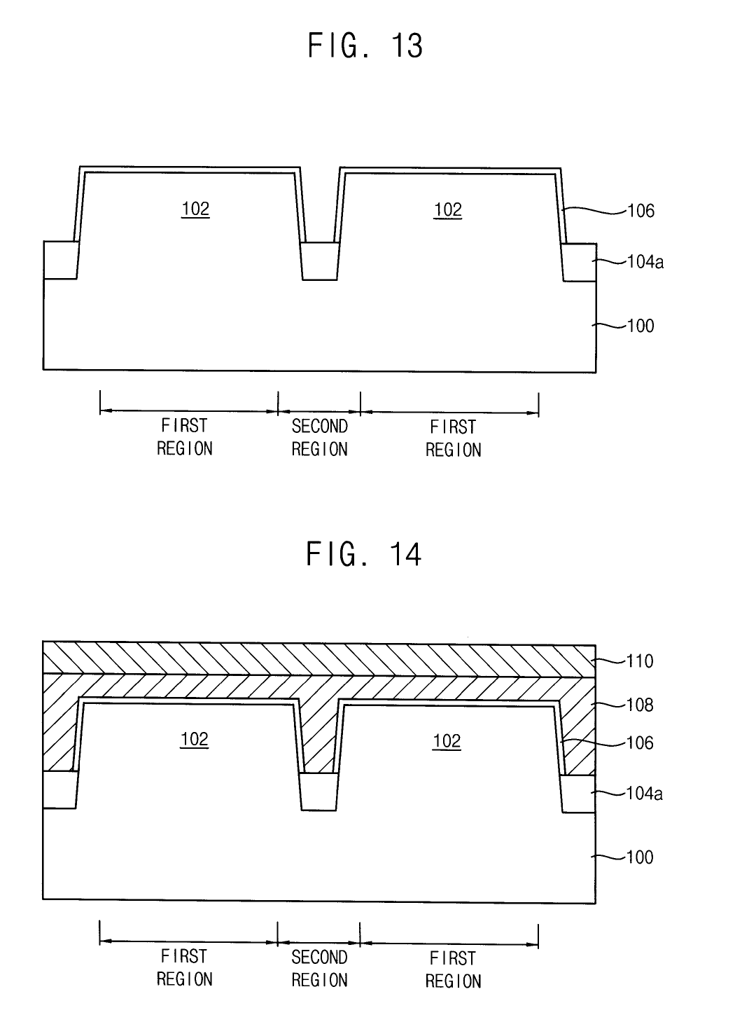

Referring to FIGS. 3 and 13, a sacrificial layer 106 may be formed on at least surfaces of the active fins 102 protruding from the upper surface of the isolation pattern 104a. The sacrificial layer 106 may protect the surfaces of the active fins 102.

The sacrificial layer 106 may include, e.g., silicon oxide or silicon oxynitride. The sacrificial layer 106 may be formed by a thermal oxidation process, a chemical vapor deposition (CVD) process, an atomic layer deposition (ALD) process, etc. When the sacrificial layer 106 may be formed by the thermal oxidation process, the sacrificial layer 106 may be formed only on the surfaces of the active fins 102. When the sacrificial layer 106 may be formed by the CVD process or the ALD process, the sacrificial layer 106 may be conformally formed on surfaces of both of the active fins 102 and the isolation pattern 104a. In some example embodiments, the sacrificial layer 106 may not be formed to simplify the process.

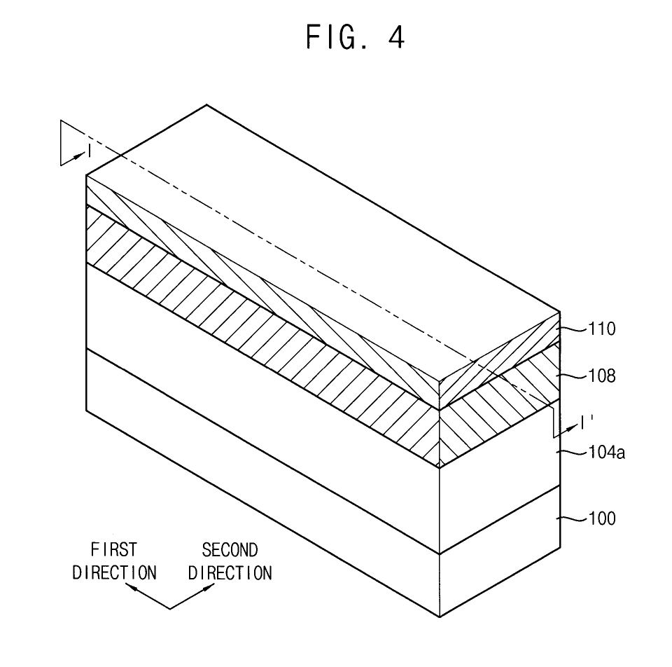

Referring to FIGS. 4 and 14, first and second mold layers 108 and 110 may be formed on the sacrificial layer 106 and the isolation pattern 104a to cover the active fins 102.

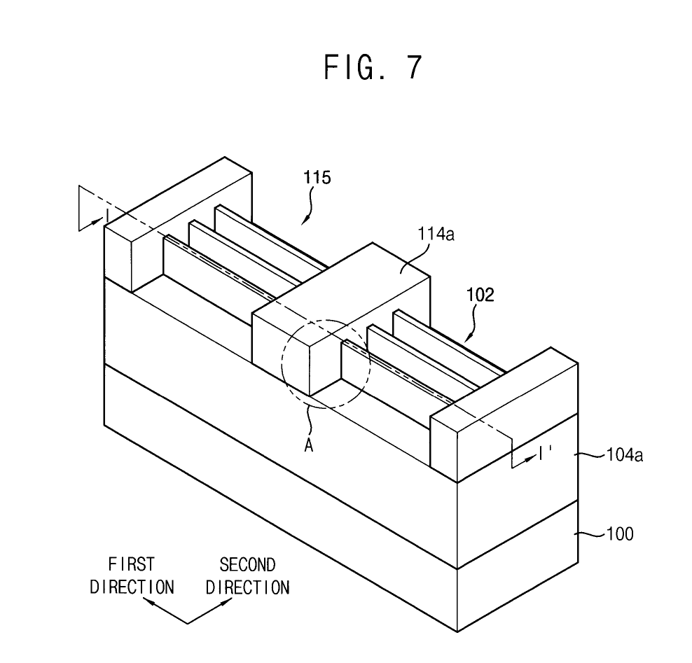

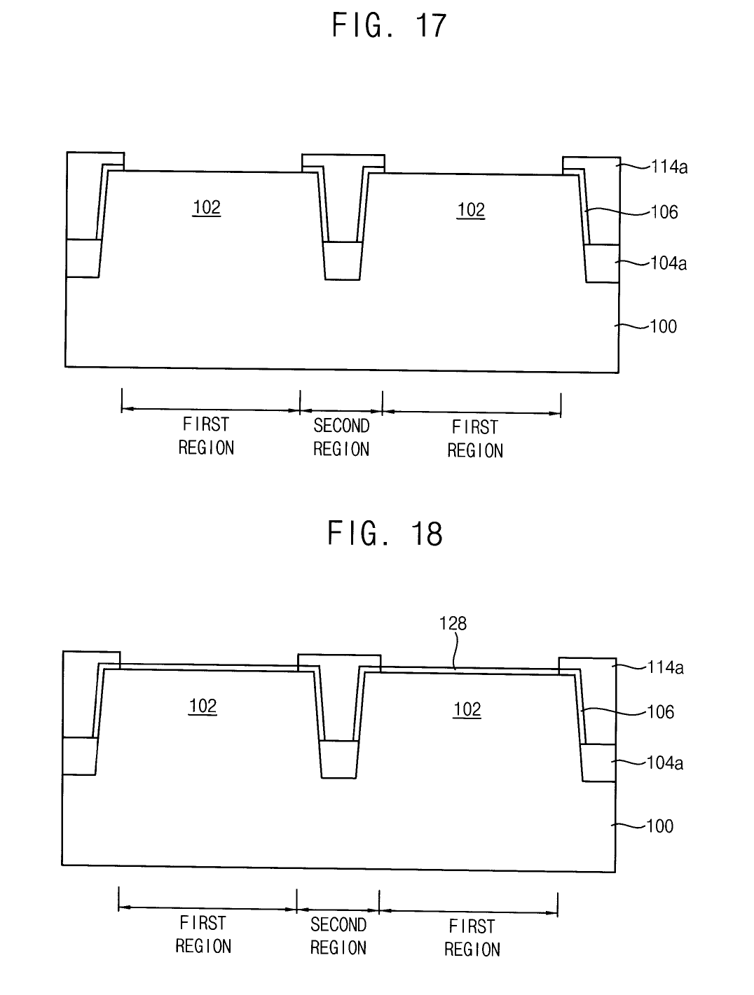

A preliminary mold layer may be formed to sufficiently cover the active fins 102. The preliminary mold layer may be planarized by a chemical mechanical polishing (CMP) process and/or an etch back process to form the first mold layer 108. The first mold layer 108 may be formed to have an upper surface higher than those of the active fins 102 so that the first mold layer 108 may cover the active fins 102. The first mold layer 108 may include a material having a high etching selectivity with respect to the active fins 102. Also, the first mold layer 108 may include a material having a high etching selectivity with respect to an insulation pattern 114a (refer to FIGS. 7 and 17) to be subsequently formed. The first mold layer 108 may include a material that may be easily removed by a wet etch process or a dry etch process. In example embodiments, the first mold layer 108 may include, e.g., polysilicon.

The second mold layer 110 may be formed on the first mold layer 108. The second mold layer 110 may include a material having a high etching selectivity with respect to the first mold layer 108. In example embodiments, the second mold layer 110 may include, e.g., silicon nitride or silicon oxynitride.

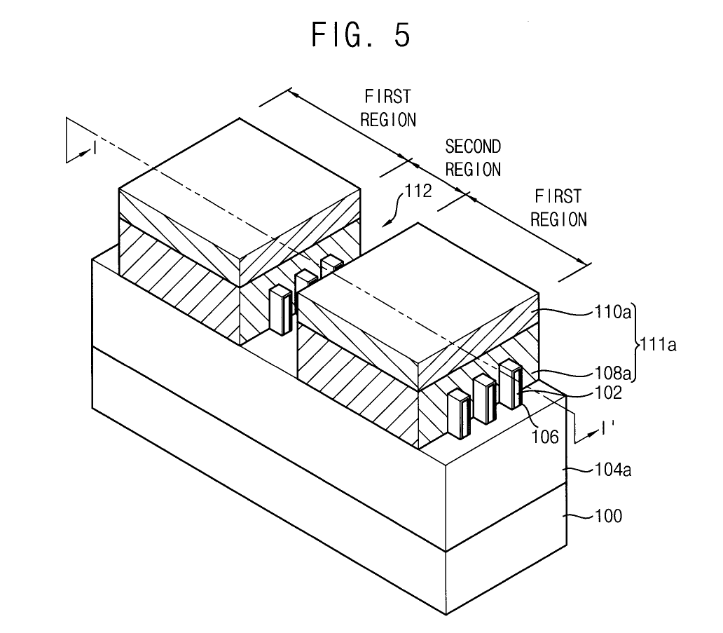

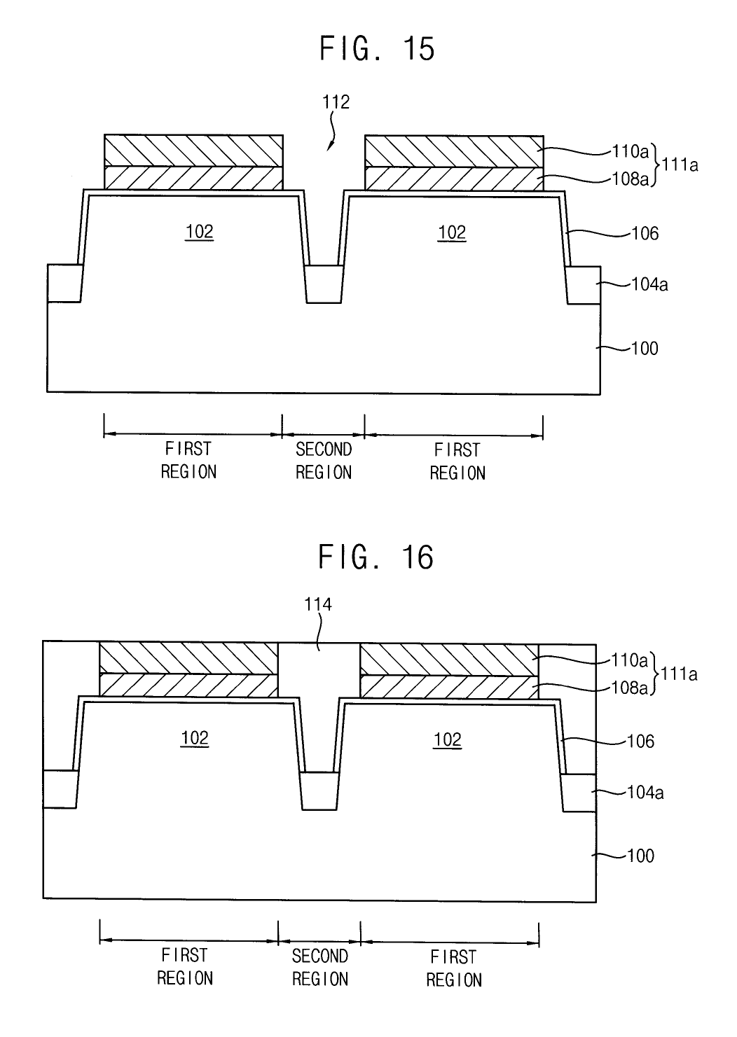

Referring to FIGS. 5 and 15, the first and second mold layers 108 and 110 may be patterned by a photolithography process to form a mold pattern structure 111a including a first mold pattern 108a and a second mold pattern 110a sequentially stacked.

A plurality of mold pattern structures 111a may be formed to cover the first region for forming the fin-type transistor, and thus the second region for forming the dummy transistor may be exposed between the mold pattern structures 111a. That is, a first opening 112 may be formed between the mold pattern structures 111a, and may extend in the second direction to expose the second region. The insulation pattern 114a may be subsequently formed in the first opening 112.

In example embodiments, both edge portions of each of the active fins 102 in the first direction may be exposed by the first opening 112, and the mold pattern structures 111a may cover a middle portion of each of the active fins 102 between the edge portions thereof. In some example embodiments, both edge portions of each of the active fins 102 in the first direction may not be exposed by the first opening 112 but may be covered by the mold pattern structures 111a.

The second mold layer 110 may be patterned by a photolithography process to form the second mold pattern 110a. The second mold pattern 110a may serve as a hard mask for etching the first mold layer 108. The first mold layer 108 may be etched using the second mold pattern 110a as an etching mask to form the first mold pattern 108a. In example embodiments, the etching process may include a dry etch process. Thus, each of the mold pattern structures 111a may be formed to include the first and second mold patterns 108a and 110a sequentially stacked.

The first mold layer 108 may have a high etching selectivity with respect to the active fins 102, and may be easily etched by an etching process. Thus, the first mold pattern 108a that may be formed by etching the first mold layer 108 may have a sidewall of which a slope may be about 80° to about 90° with respect to the top surfaces of the active fins 102. In example embodiments, the slope of the sidewall of the first mold pattern 108a may be substantially 90°, and thus a sidewall of the first opening 112 may have a slope of substantially 90°.

The first openings 112 may be formed to have a small difference between a maximum slope of the sidewall and a minimum slope of the sidewall. In example embodiments, the difference between the maximum slope of the sidewall and the minimum slope of the sidewall may be less than about 20% of the maximum slope of the sidewall. Thus, the first opening 112 may be formed to have a small difference between a maximum width in the first direction and a minimum width in the first direction. In example embodiments, the difference between the maximum width of the first opening 112 in the first direction and the minimum width of the first opening 112 in the first direction may be less than about 20% of the maximum width of the first opening 112 in the first direction.

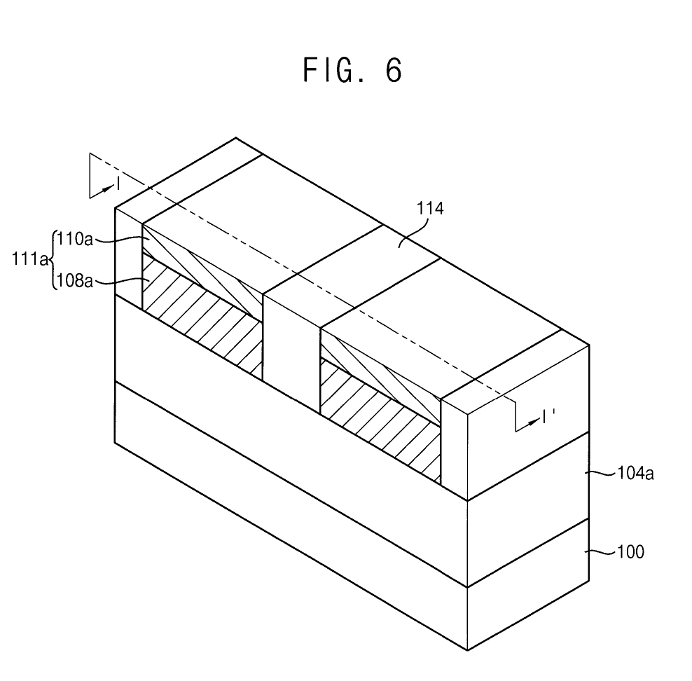

Referring to FIGS. 6 and 16, an insulation layer may be formed to sufficiently fill the first opening 112, and may be planarized, until a top surface of the second mold pattern 110a may be exposed, to form a preliminary insulation pattern 114. In example embodiments, the planarization process may be performed by a CMP process and/or an etch back process.

The insulation layer may include an oxide, e.g., silicon oxide. That is, the insulation layer may include a material substantially the same as the isolation pattern 104a.

Referring to FIGS. 7 and 17, an upper portion of the preliminary insulation pattern 114 may be etched to form the insulation pattern 114a. In some example embodiments, a top surface of the insulation pattern 114a may be substantially coplanar with top surfaces of the active fins 102. In other example embodiments, the top surface of the insulation pattern 114a may be slightly lower than or slightly higher than the top surfaces of the active fins 102. FIGS. 7 and 17 show that the insulation pattern 114a has the top surface slightly higher than the top surfaces of the active fins 102.

In example embodiments, a height of the insulation pattern 114a may be controlled by thicknesses of the first and second mold patterns 108a and 110a. Thus, the etching process of the preliminary insulation pattern 114 for controlling the height of the insulation pattern 114a may be skipped to simplify the process. In some example embodiments, a plurality of the insulation patterns 114a may be formed.

The mold pattern structures 111a and the sacrificial layer 106 may be removed to form a second opening 115 between the insulation patterns 114a. A bottom of the second opening 115 may expose the isolation pattern 104a, and the active fins 102 may protrude from the upper surface of the isolation pattern 104a.

The insulation pattern 114a may be formed in the first opening 112 so that a sidewall profile of the insulation pattern 114a may be substantially the same as that of the first opening 112. Thus, a slope of a sidewall of the insulation pattern 114a may be in a range of about 80° to about 90°, and preferably but not necessarily, the slope of a sidewall of the insulation pattern 114a may be substantially 90°. Also, a difference between a slope of an upper sidewall of the insulation pattern 114a and a slope of a lower sidewall of the insulation pattern 114a may be small.

In example embodiments, a difference between the maximum slope of the sidewall of the insulation pattern 114a and the minimum slope thereof may be less than about 20% of the maximum slope thereof. That is, the difference between the maximum width in the first direction of the insulation pattern 114a and the minimum width in the first direction thereof may be less than about 20% of the maximum width in the first direction thereof.

FIG. 10A is an enlarged view illustrating a portion “A” of FIG. 7, and FIG. 10B shows a portion of an insulation pattern of a related art semiconductor device for comparison with the portion A shown in FIG. 10A.

Referring to FIG. 10B, in the related art semiconductor device, an insulation layer may be patterned by a photolithography process to form an insulation pattern 114b. A portion of the insulation layer in a narrow space between active fins 103 may not be easily removed. For example, a portion of the insulation layer in a lower portion of the space between the active fins 103 may not be easily removed. Thus, a sidewall of the insulation pattern 114b may not have a vertical slope, and may have a tail portion “t” having a relatively wide width at a lower portion thereof between the active fins 103. The tail portion “t” of the insulation pattern 114b may partially cover a sidewall of the active fins 103 so that an effective active region of the active fins 103 may decrease. Thus, impurity regions and a channel region of the fin-type transistor may decrease. According to a length of the tail portion “t” of the insulation pattern 114b in the first direction, the effective active regions of the active fins 103 may change, and may not be uniform. Thus, electrical characteristics of the fin-type transistor formed on the active fins 103 may not be uniform.

Referring to FIG. 10A, in example embodiments, the insulation pattern 114a may be formed by a damascene process so that the sidewall of the insulation pattern 114a may have a substantially vertical slope. Also, no tail portion may be formed at a lower portion between the active fins 102. Thus, the effective active region of the active fins 102 may increase, and may be uniform, so that the fin-type transistor may be formed to have enlarged impurity regions and a channel region, and the fin-type transistor may have uniform electrical characteristics.

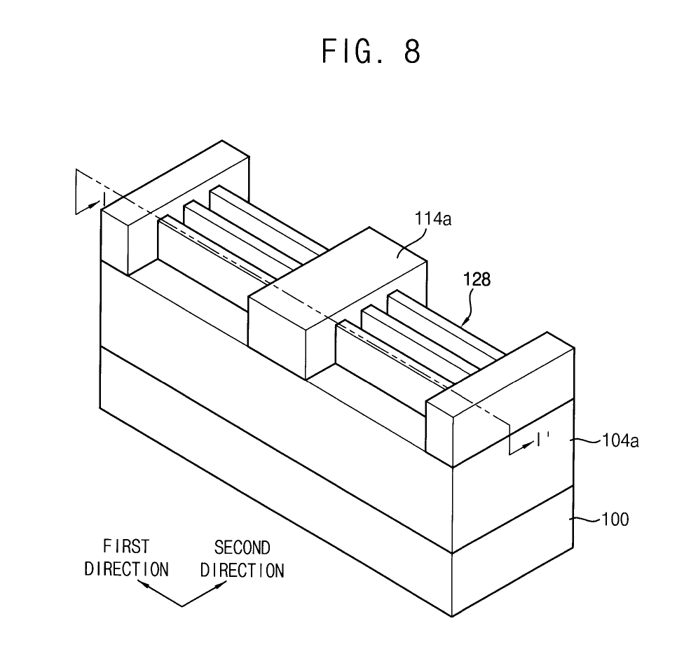

Referring to FIGS. 8 and 18, a gate insulation layer 128 may be formed on the active fins 102. The gate insulation layer 128 may include an oxide, e.g., silicon oxide, silicon oxynitride, a metal oxide, etc. The gate insulation layer 128 may be formed to have a single layer or a plurality of layers. The metal oxide may have a dielectric constant higher than that of silicon oxide, and may include, e.g., hafnium oxide, tantalum oxide, zirconium oxide, etc. The gate insulation layer 128 may be formed by a thermal oxidation process, a CVD process, an ALD process, etc.

When the gate insulation layer 128 may be formed by the thermal oxidation process, the gate insulation layer 128 may be formed only on the surfaces of the active fins 102. In some example embodiments, when the gate insulation layer 128 may be formed by the CVD process or the ALD process, the gate insulation layer 128 may be conformally formed on the active fins 102, the insulation pattern 114a and the isolation pattern 104a.

Referring to FIGS. 9, 19A and 19B, a gate structure 122 extending in the second direction may be formed on the active fins 102, and a dummy gate structure 124 extending in the second direction may be formed on the insulation pattern 114a.

A gate electrode layer (not shown) may be formed on the gate insulation layer 128 and the insulation pattern 114a to fill a space between the active fins 102. An upper portion of the gate electrode layer may be planarized by a CMP process and/or an etch back process. After the planarization process, a top surface of the gate electrode layer may be higher than those of the active fins 102, and thus the gate electrode layer may cover the active fins 102.

First and second hard masks 118a and 118b may be formed on the gate electrode layer. The first hard mask 118a may extend in the second direction to traverse the active fins 102. The second hard mask 118b may extend in the second direction on a portion of the insulation pattern 114a. The gate electrode layer may be etched using the first and second hard masks 118a and 118b as etching masks to form a first gate electrode 116a and a second gate electrode 116b, respectively. The first gate electrode 116a may be formed to traverse the active fins 102, and the second gate electrode 116b may be formed on the insulation pattern 114a.

Thus, a gate structure 122 including the gate insulation layer 128, the first gate electrode 116a and the first hard mask 118a sequentially stacked may be formed on the active fins 102 and the isolation pattern 104a. Also, a dummy gate structure 124 including the second gate electrode 116b and the second hard mask 118b sequentially stacked may be formed on the insulation pattern 114a. In example embodiments, a bottom surface of the gate structure 122 may be lower than that of the dummy gate structure 124.

A spacer layer may be conformally formed on the gate structure 122, the dummy gate structure 124, the insulation pattern 114a and the isolation pattern 104a. The spacer layer may include an insulation material, e.g., silicon nitride, silicon oxide, etc. The spacer layer may be formed by a CVD process, an ALD process, etc. The spacer layer may be anisotropically etched to form spacers 120 on sidewalls of the gate structure 122 and the dummy gate structure 124.

Impurities may be doped into the active fins 102 to form impurity regions (not shown). The impurity regions may serve as source/drain regions of the fin-type transistor.

As illustrated above, according to the example embodiments, the gate electrode layer may be patterned by a photolithography process to form the gate structure 122 and the dummy gate structure 124. In some example embodiments, the gate structure 122 and the dummy gate structure 124 may be formed by a gate last process. For example, after a sacrificial mold layer including openings (not shown) therethrough may be formed on the active fins 102, the insulation pattern 114a and the isolation pattern 104a , the gate insulation layer 128 and the gate structure 122 and the dummy gate structure 124 may be formed to fill the openings.

The exposed active fins 102 adjacent to the gate structure 122 may be electrically connected to one another. For example, a plurality of source regions at portions of the active fins 102 adjacent to one side of the gate structure 122 may be electrically connected to one another, so that the source regions may serve as one source region. Also, a plurality of drain regions at portions of the active fins 102 adjacent to another side of the gate structure 122 may be electrically connected to one another, so that the drain regions may serve as one drain region. In some example embodiments, the source and drain regions may include an epitaxial layer. The epitaxial layers may be formed on the active fins 102 by a selective epitaxial growth (SEG) process and may be connected to one another.

As illustrated above, the fin-type transistor may be formed on the active fins 102, and a dummy transistor that may not be actually operated may be formed on the insulation pattern 114a. The sidewall of the insulation pattern 114a formed under the dummy transistor may have a substantially vertical slope, so that the effective active region of active fins 102 adjacent to the insulation pattern 114a may increase, and may be uniform. Thus, the impurity regions and the channel region of the fin-type transistor may not decrease, and the fin-type transistor may have uniform electrical characteristics.

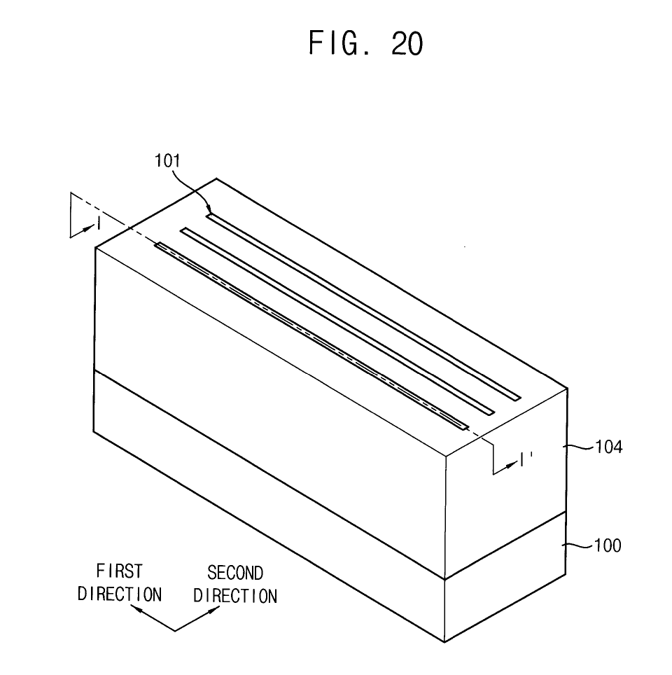

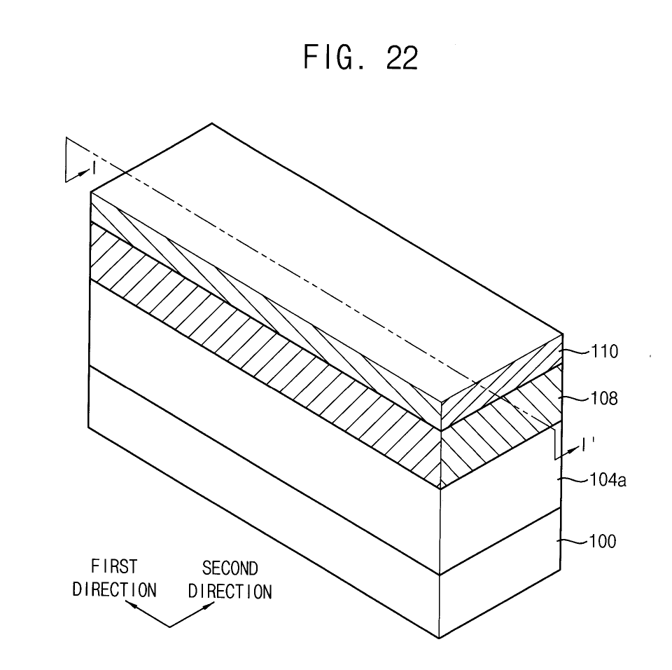

FIGS. 20 to 31 are perspective views and cross-sectional views illustrating stages of a method of manufacturing a semiconductor device in accordance with other example embodiments.

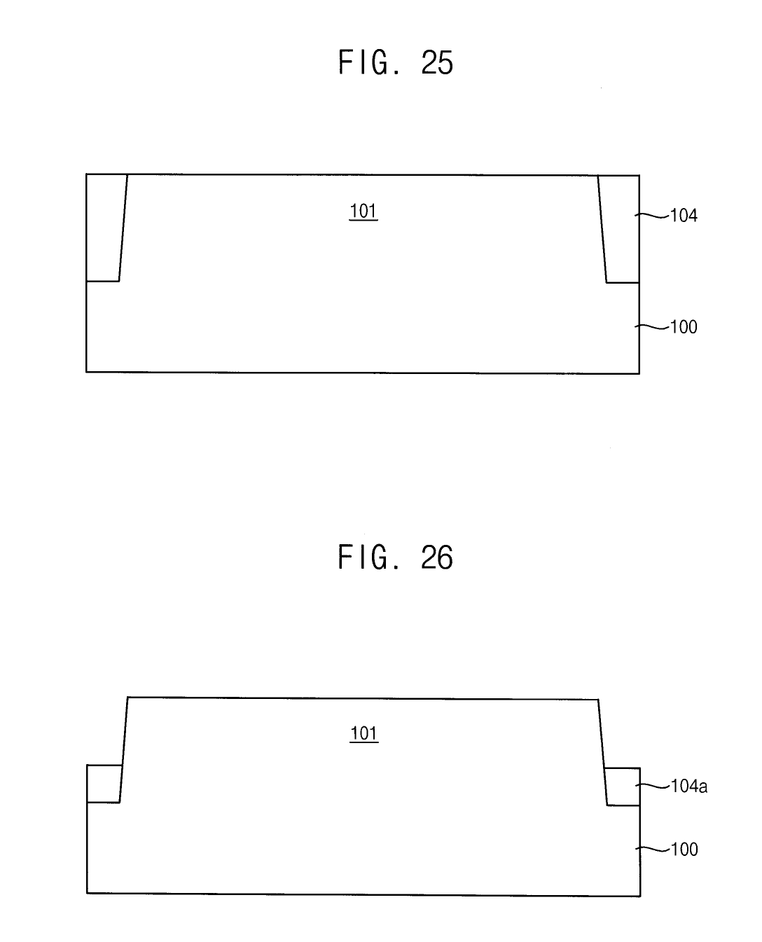

FIGS. 25 to 31A show cross-sectional views taken along a line I-I′ of FIGS. 20 to 24, respectively.

Referring to FIGS. 20 and 25, a substrate 100 may be partially etched to form preliminary active fins 101, and a preliminary isolation layer 104 may be formed on the substrate 100 between the preliminary active fins 101.

An upper portion of a substrate 100 may be partially removed to form the preliminary active fins 101 and trench (not shown) therebetween. Each of the preliminary active fins 101 may extend in a first direction, and may not be removed at a region for forming a dummy transistor. The preliminary active fins 101 may be formed in a second direction substantially perpendicular to the first direction.

An insulation layer may be formed on the substrate 100 to sufficiently fill the trench, and may be planarized until top surfaces of the preliminary active fins 101 may be exposed to form the preliminary isolation layer 104. The insulation layer may include an oxide, e.g., silicon oxide.

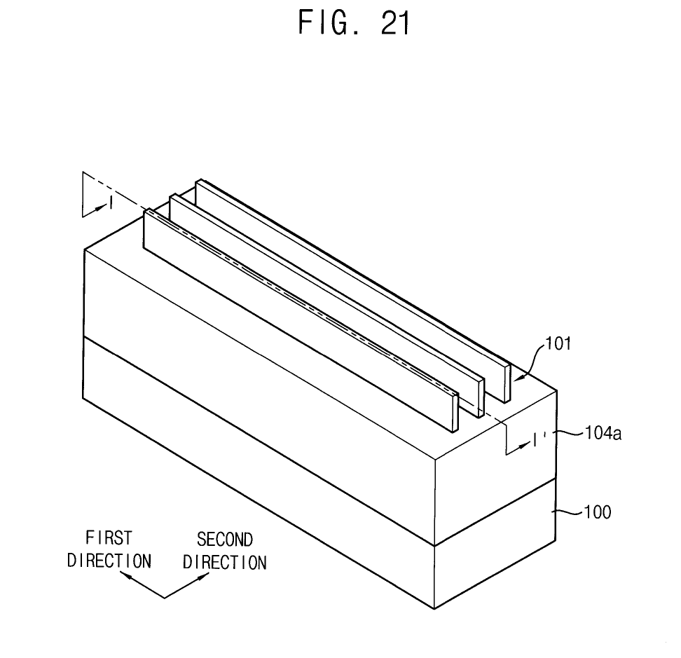

Referring to FIGS. 21 and 26, an upper portion of the preliminary isolation layer 104 may be etched to expose upper sidewalls of the preliminary active fins 101, and an isolation pattern 104a filling a lower portion of the trench may be formed.

In example embodiments, impurities may be lightly doped into upper portions of the preliminary active fins 101 to control a threshold voltage of a fin-type transistor.

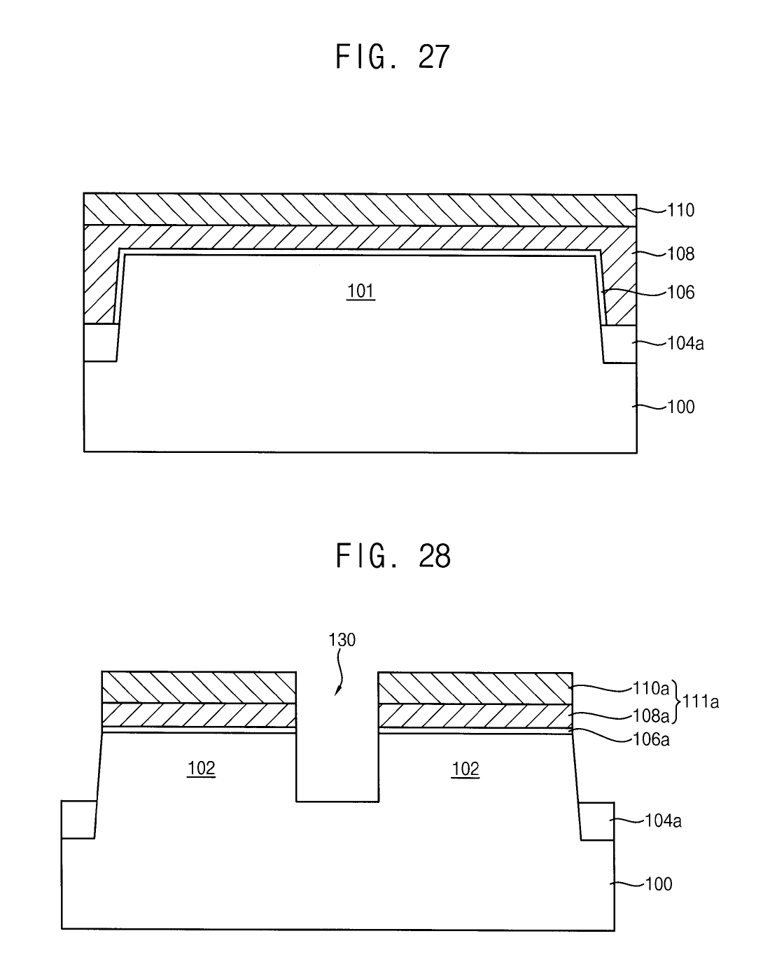

Referring to FIG. 27, a sacrificial layer 106 may be formed on at least surfaces of the preliminary active fins 101. First and second mold layers 108 and 110 may be formed on the sacrificial layer 106 and the isolation pattern 104a to cover the preliminary active fins 101.

The sacrificial layer 106 and the first and second mold layers 108 and 110 may be formed by performing processes substantially the same as or similar to those illustrated in FIGS. 3, 4, 13, and 14.

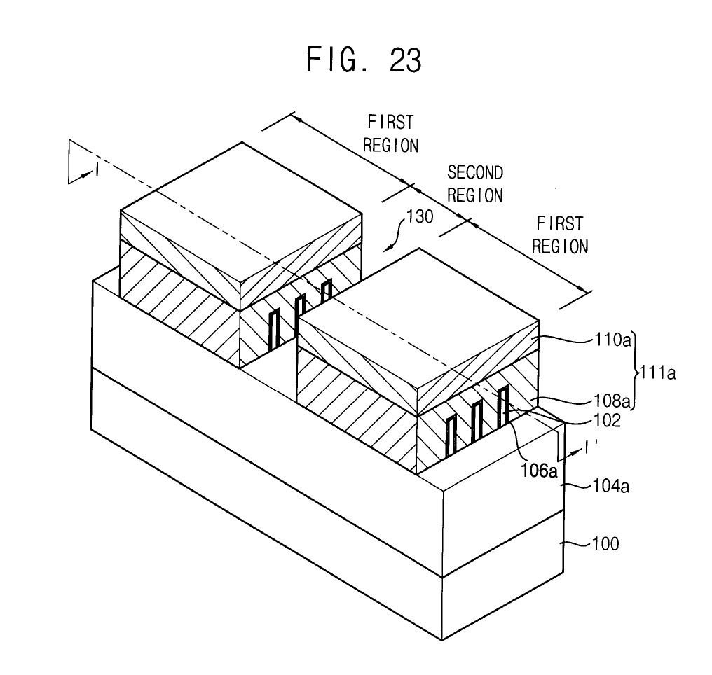

Referring to FIGS. 23 and 28, the first and second mold layers 108 and 110 may be patterned to form a mold pattern structure 111a including a first mold pattern 108a and a second mold pattern 110a sequentially stacked. A plurality of mold pattern structures 111a may be formed to cover a first region for forming the fin-type transistor, and thus a second region for forming the dummy transistor may be exposed between the mold pattern structures 111a.

The exposed sacrificial layer 106 and the preliminary active fins 101 between the mold pattern structures 111a may be etched to form a sacrificial pattern 106a and active fins 102, respectively. The active fins 102 may be formed to be spaced apart from one another in the first direction.

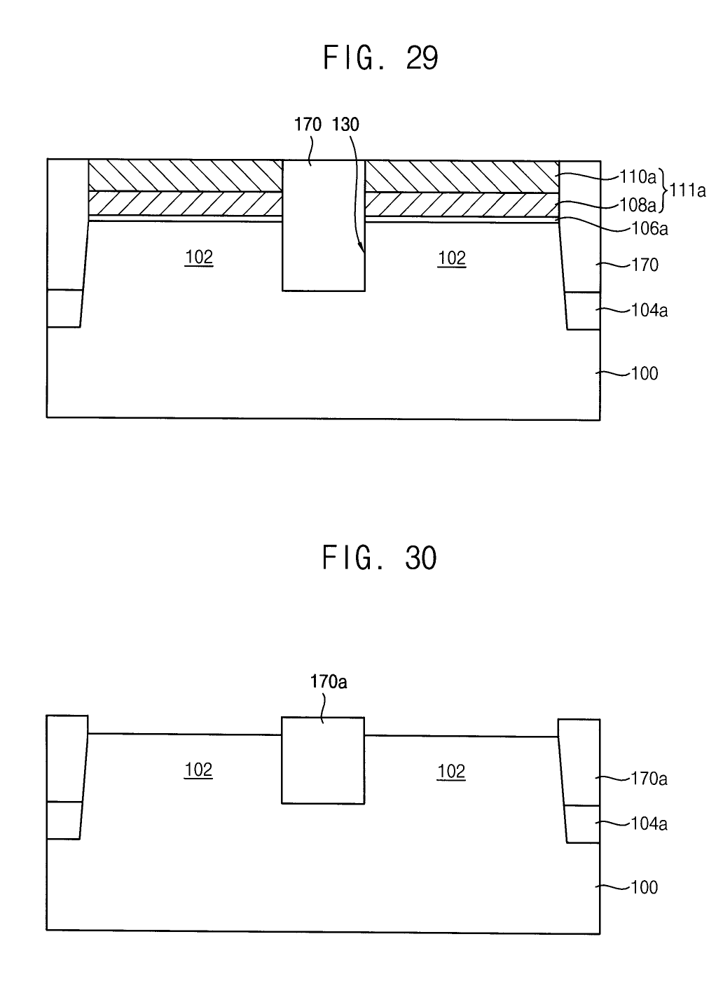

Thus, a first opening 130 extending in the second direction may be formed between the mold pattern structures 111a. The first opening 130 may be formed at the second region, and an insulation pattern 170a (refer to FIG. 29) may be subsequently formed in the first opening 130. In example embodiments, both sidewalls of each of the active fins 102 in the first direction may be exposed by the first opening 130, and the mold pattern structures 111a may cover other portions of the active fins 102.

The second mold layer 110 may be patterned by a photolithography process to form the second mold pattern 110a. The first mold layer 108 may be etched using the second mold pattern 110a as an etching mask to form the first mold pattern 108a. In example embodiments, the etching process may include a dry etch process. Thus, a plurality of mold pattern structures 111a may be formed to include the first and second mold patterns 108a and 110a sequentially stacked. The exposed preliminary active fins 101 between the mold pattern structures 111a may be etched to form the active fins 102.

A slope of a sidewall of the first opening 130 may be substantially 90°. Also, the first opening 130 may be formed to have a small difference between a slope of an upper sidewall of the first opening 130 and a slope of a lower sidewall thereof. In example embodiments, the difference between a maximum slope of the sidewall of the first opening 130 and a minimum slope thereof may be less than about 20% of the maximum slope thereof.

Thus, the first opening 130 may be formed to have a small difference between a maximum width in the first direction and a minimum width in the first direction. In example embodiments, the difference between the maximum width in the first direction of the first opening 130 and the minimum width in the first direction thereof may be less than about 20% of the maximum width in the first direction thereof.

Then, processes substantially the same as or similar to those illustrated with reference to FIGS. 6 and 7 may be performed.

Referring to FIG. 29, an insulation layer may be formed to sufficiently fill the first opening 130, and may be planarized until a top surface of the second mold pattern 110a may be exposed to form a preliminary insulation pattern 170.

Referring to FIG. 30, an upper portion of the preliminary insulation pattern 170 may be etched to form an insulation pattern 170a. In example embodiments, a top surface of the insulation pattern 170a may be substantially coplanar with top surfaces of the active fins 102. In some example embodiments, the top surface of the insulation pattern 170a may be slightly lower than or slightly higher than the top surfaces of the active fins 102. However, the etching process of the preliminary insulation pattern 170 for controlling a height of the insulation pattern 170a may be skipped to simplify the process. In example embodiments, a plurality of the insulation patterns 170a may be formed.

The mold pattern structure 111a may be removed to form a second opening 115 (refer to FIGS. 7 and 17) between the insulation patterns 170a. A bottom of the second opening 115 may expose the isolation pattern 104a, and the active fins 102 may protrude from an upper surface of the isolation pattern 104a.

The insulation pattern 170a may be formed by a damascene process so that the slope of the sidewall of the insulation pattern 170a may be in a range of about 80 to about 90°. As shown in FIG. 7, the slope of the sidewall of the insulation pattern 170a may be substantially 90°. Also, a width of the insulation pattern 170a may be uniform, and a lower width of the insulation pattern 170a may not be increased.

Thus, an effective active region of the active fins 102 may increase, and may be uniform. The fin-type transistor may be formed to have enlarged impurity regions and a channel region, and the fin-type transistor may have uniform electrical characteristics.

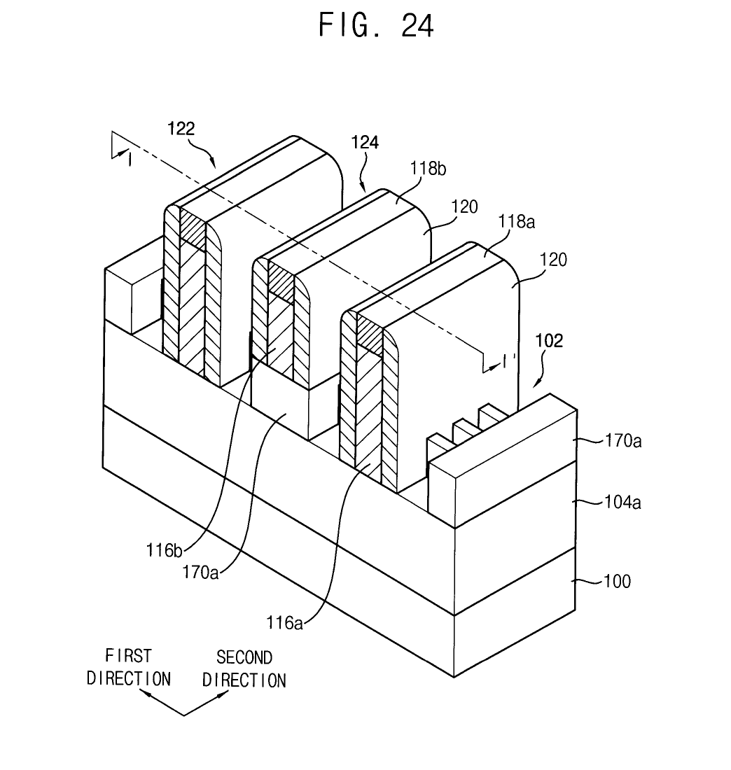

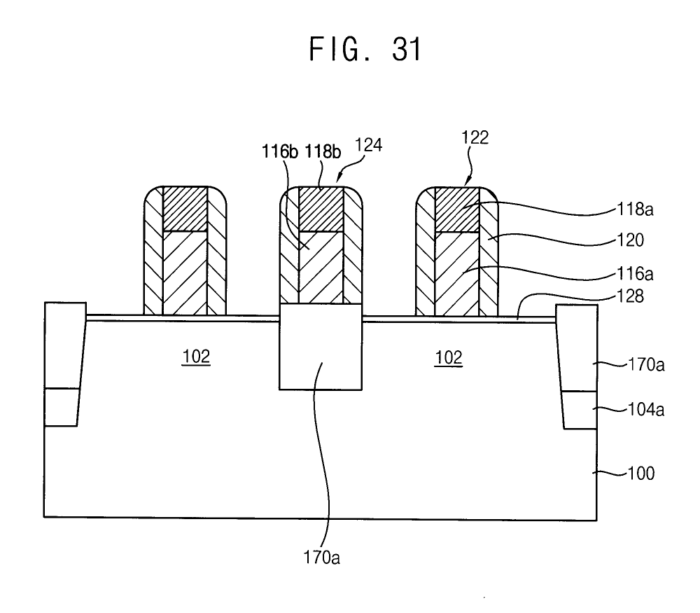

Referring to FIGS. 24 and 31, a gate structure 122 extending the second direction may be formed on the active fins 102, and a dummy gate structure 124 extending the second direction may be formed on the insulation pattern 170a. Spacers 120 may be formed on sidewalls of the gate structure 122 and the dummy gate structure 124, respectively. Impurities may be doped into the active fins 102 between the gate structure 122 and the dummy gate structure 124 to form impurity regions (not shown).

Thus, the fin-type transistor may be formed on the active fins 102 and the isolation pattern 104a, and a dummy transistor that may not be actually operated may be formed on the insulation pattern 170a. The above processes for forming the gate structure 122, the dummy gate structure 124 and the spacers 120 may be substantially the same as or similar to those illustrated with reference to FIGS. 8, 9, 18, 19A and 19B.

As illustrated above, the fin-type transistor may be formed to have the enlarged impurity regions and channel region. Also, the semiconductor device may include the fin-type transistor having uniform electrical characteristics.

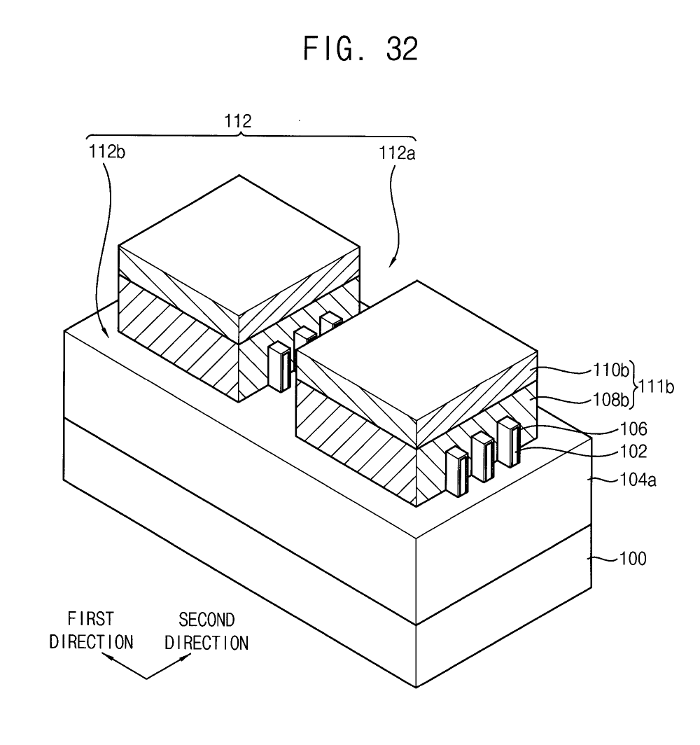

FIGS. 32 to 38, 39A and 39B are perspective views and cross-sectional views illustrating stages of a method of manufacturing a semiconductor device in accordance with still other example embodiments.

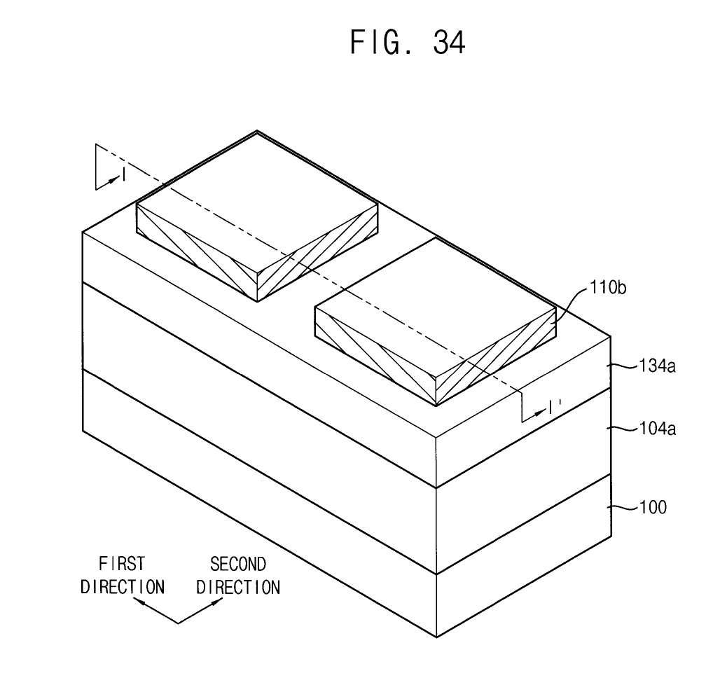

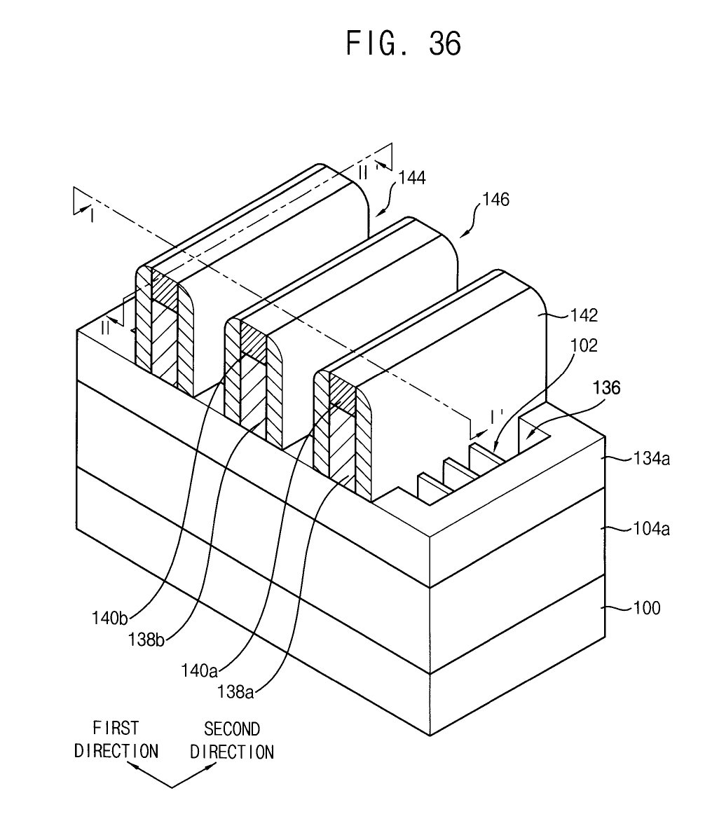

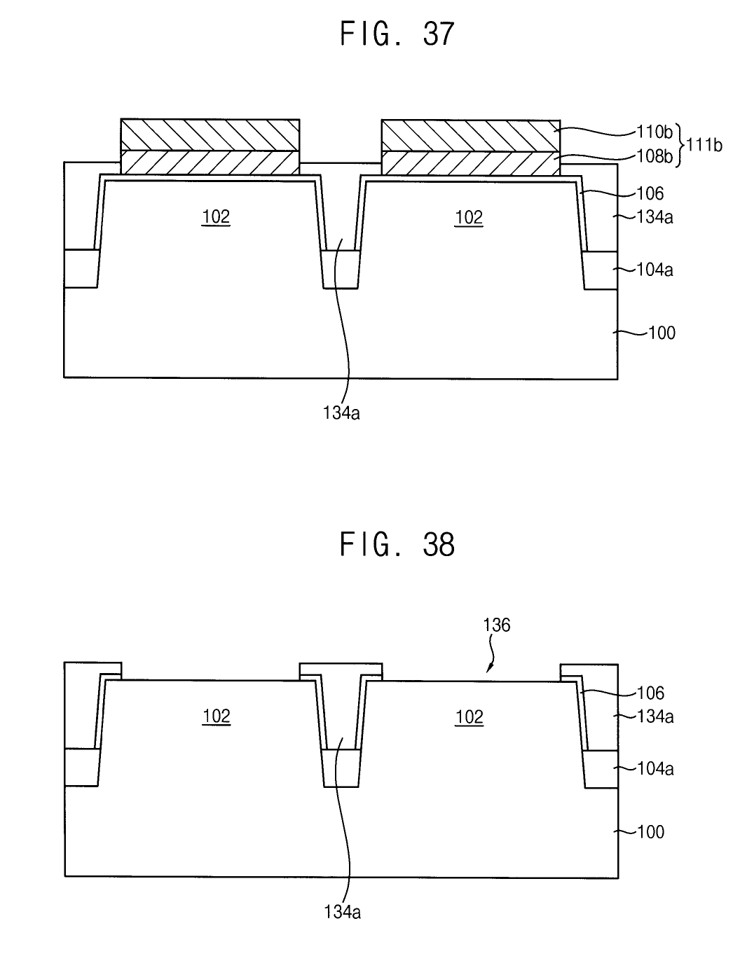

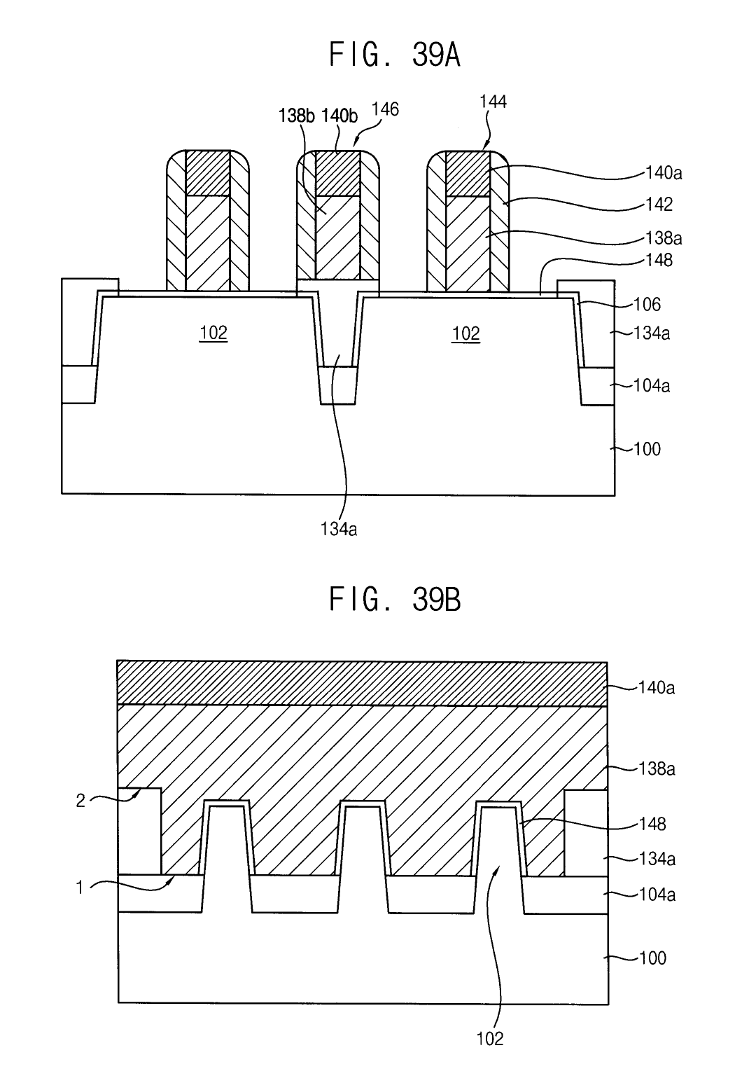

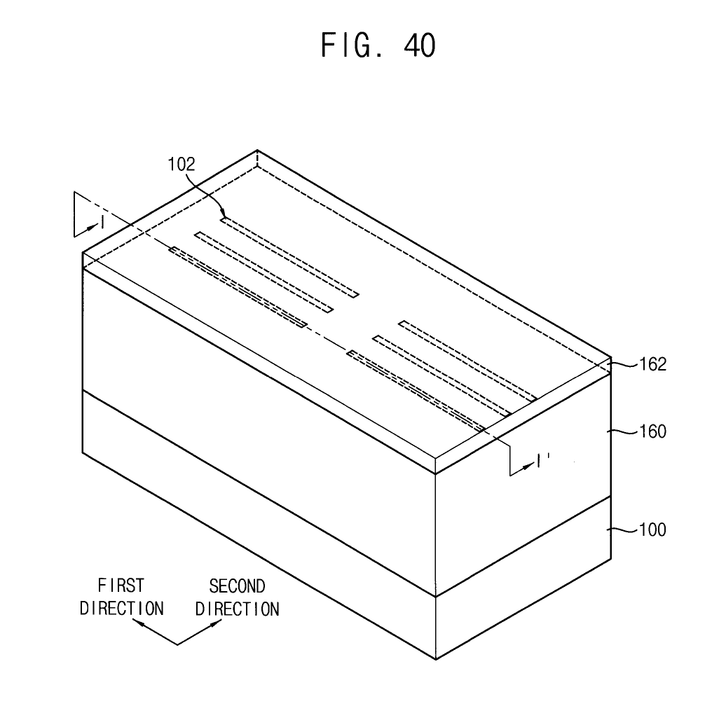

FIGS. 37, 38 and 39A show cross-sectional views taken along a line I-I′ of FIGS. 34 to 36, respectively, and FIG. 39B show cross-sectional views taken along a line II-II′ of FIG. 36.

First, processes substantially the same as or similar to those illustrated with reference to FIGS. 1 to 4 may be performed to form first and second mold layers on the sacrificial layer 106 and the isolation pattern 104a to cover the active fins 102.

Referring to FIG. 32, the first and second mold layers 108 and 110 may be patterned to form a mold pattern structure 111b including a first mold pattern 108b and a second mold pattern 110b sequentially stacked.

A plurality of mold pattern structures 111b may be formed to have an island shape from one another to cover only a first region for forming the fin-type transistor. That is, a first opening 112 may be formed between the mold pattern structures 111a, and may have a first portion 112a extending in the second direction to expose the second region and a second portion 112b extending in the first direction. Thus, the first opening 112 may have a grid shape.

The second mold layer 110 may be patterned by a photolithography process to form the second mold pattern 110b. The first mold layer 108 may be etched using the second mold pattern 110b as an etching mask to form the first mold pattern 108b. In example embodiments, the etching process may include a dry etch process.

The first mold pattern 108b that may be formed by etching the first mold layer 108 may have a sidewall of which a slope may be about 80° to about 90° with respect to the top surfaces of the active fins 102, and thus a sidewall of the first opening may have a slope of about 80° to about 90°. In example embodiments, the slope of the sidewall of the first mold pattern 108b may be substantially 90°, and thus a sidewall of the first opening 112 may have a slope of substantially 90°.

The first openings 112 may be formed to have a small difference between a slope of an upper sidewall of the first opening 112 and a slope of a lower sidewall of the first opening 112. In example embodiments, the difference between the maximum slope of the sidewall of the first opening 112 and the minimum slope thereof may be less than about 20% of the maximum slope thereof. Thus, the first portion 112a of the first opening 112 may be formed to have a small difference between a maximum width in the first direction and a minimum width in the first direction. In example embodiments, the difference between the maximum width in the first direction of the first portion 112a and the minimum width in the first direction thereof may be less than about 20% of the maximum width in the first direction thereof.

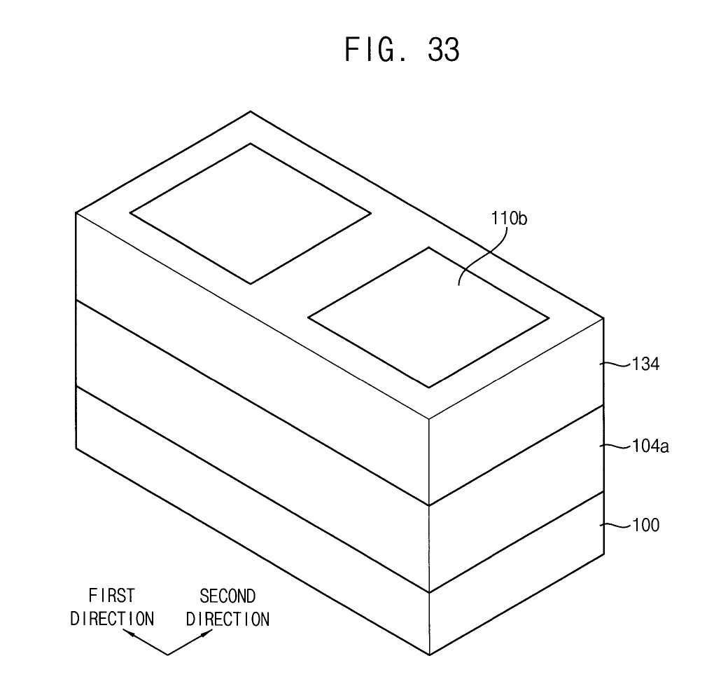

Referring to FIG. 33, an insulation layer may be formed to sufficiently fill the first opening, and the insulation layer may be planarized until a top surface of the second mold pattern 110b may be exposed to form a preliminary insulation pattern 134. In example embodiments, the planarization process may be performed by a CMP process and/or an etch back process. The preliminary insulation pattern 134 may have the grid pattern substantially the same as that of the first opening.

The insulation layer may to include an oxide, e.g., silicon oxide. The insulation layer may include a material substantially the same as that of the isolation pattern 104a.

Referring to FIGS. 34 and 37, an upper portion of the preliminary insulation pattern 134 may be etched to form an insulation pattern 134a. In example embodiments, a top surface of the insulation pattern 134a may be substantially coplanar with top surfaces of the active fins 102. Alternatively, the top surface of the insulation pattern 134a may be slightly lower than or slightly higher than the top surfaces of the active fins 102.

In example embodiments, a height of the insulation pattern 134a may be controlled by thicknesses of the first and second mold patterns 108b and 110b. Thus, the etching process of the preliminary insulation pattern 134 for controlling the height of the insulation pattern 134a may be skipped to simplify the process.

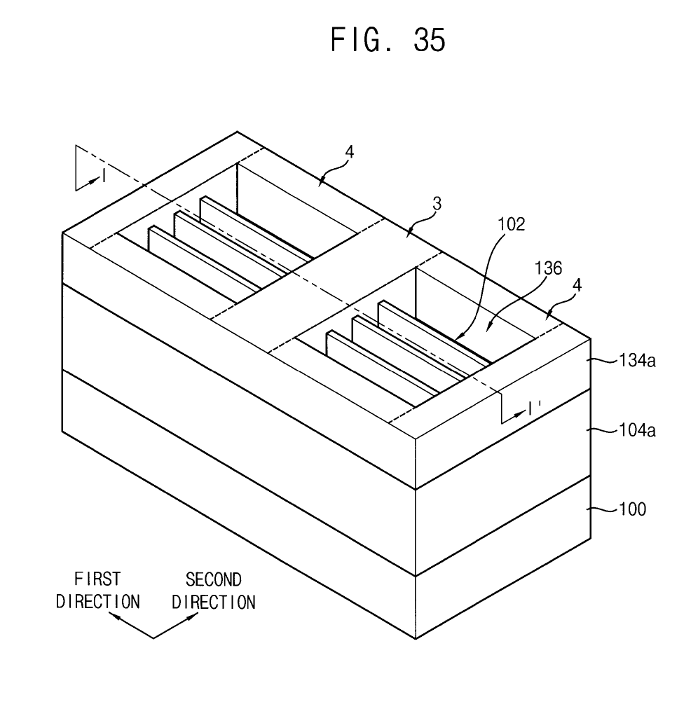

Referring to FIGS. 35 and 38, the mold pattern structures 111b and the sacrificial layer 106 may be removed to form a second opening 136. A bottom of the second opening 136 may expose the isolation pattern 104a, and the active fins 102 may protrude from the upper surface of the isolation pattern 104a.

The insulation pattern 134a may include a third portion 3 for forming a dummy gate structure and a fourth portion 4 for forming a gate structure of a fin-type transistor, and may have the grid shape. The third portion 3 may extend in the second direction and the fourth portion 4 may extend in the first direction.

The insulation pattern 134a may be formed in the first opening so that a sidewall profile of the insulation pattern 134a may be substantially the same as that of the first opening. Thus, a slope of a sidewall of the insulation pattern 134a may be in a range of about 80° to about 90°, and preferably but not necessarily, the slope of a sidewall of the insulation pattern 134a may be substantially 90°. Also, a difference between a slope of an upper sidewall of the insulation pattern 134a and a slope of a lower sidewall of the insulation pattern 134a may be small. Thus, a difference between an upper width in the first direction of the insulation pattern 134a and a lower width in the first direction thereof may be small.

In example embodiments, a difference between the maximum slope of the sidewall of the insulation pattern 134a and the minimum slope thereof may be less than about 20% of the maximum slope thereof. That is, the difference between the maximum width in the first direction of the insulation pattern 134a and the minimum width in the first direction thereof may be less than about 20% of the maximum width in the first direction thereof.

The sidewall of the insulation pattern 134a may have a substantially vertical slope so that an effective active region of the active fins 102 may increase and may be uniform. Thus, the fin-type transistor may be formed to have enlarged impurity regions and a channel region, and the fin-type transistor may have uniform electrical characteristics.

Referring to FIGS. 36, 39A and 39B, a gate structure 144 extending in the second direction may be formed on the active fins 102, and a dummy gate structure 146 extending in the second direction may be formed on the insulation pattern 134a. The gate structure 144 may be formed on the fourth portion 4 of the insulation pattern 134a that may be parallel to the active fins 102, and in the second opening 136.

A gate insulation layer 148 may be formed on the active fins 102. The gate insulation layer 148 may be formed by performing a process substantially the same as or similar to that illustrated in FIGS. 8 and 18.

A gate electrode layer (not shown) may be formed on the gate insulation layer 128 to fill the second opening 136 and to cover the active fins 102. A plurality of second openings 136 may be formed to have an island shape from one another, and a top surface of the insulation pattern 134a may be substantially flat. A space between the active fins 102 in the second opening may be small. Thus, top surface of the gate electrode layer may be substantially flat, and a planarization process of the gate electrode layer may be skipped to simplify the process.

First and second hard masks 140a and 140b may be formed on the gate electrode layer. The first hard mask 140a may extend in the second direction to traverse the active fins 102. The second hard mask 140b may extend in the second direction on the insulation pattern 134a. The gate electrode layer may be etched using the first and second hard masks 140a and 140b as etching masks to form a first gate electrode 138a and a second gate electrode 138b, respectively. The first gate electrode 138a may be formed to traverse the active fins 102, and the second gate electrode 138b may be formed on the insulation pattern 134a.

Thus, a gate structure 144 including the gate insulation layer 148, the first gate electrode 138a and the first hard mask 140a sequentially stacked may be formed on the active fins 102 and the fourth portion 4 of the insulation pattern 134a. Also, a dummy gate structure 146 including the second gate electrode 138b and the second hard mask 140b sequentially stacked may be formed on the third portion 3 of the insulation pattern 134a. A bottom surface of the gate structure 144 may be disposed at the fourth portion 4 of the insulation pattern 134a and sidewalls and top surfaces of the active fins 102. That is, the bottom surface of the gate structure 144 may have a first bottom surface 1 on the isolation pattern 104a and a second bottom surface 2 on the fourth portion 4 of the insulation pattern 134a, and the second bottom surface 2 may be higher than the first bottom surface 1. Also, the second bottom surface 2 of the gate structure 144 may be coplanar with a bottom surface of the dummy gate structure 146.

A spacer layer may be conformally formed on the gate structure 144, the dummy gate structure 146, the insulation pattern 134a and the isolation pattern 104a. The spacer layer may be anisotropically etched to form spacers 142 on sidewalls of the gate structure 144 and the dummy gate structure 146.

Impurities may be doped into the active fins 102 to form impurity regions (not shown). The impurity regions may serve as source/drain regions of the fin-type transistor. Thus, the fin-type transistor may be formed on the active fins 102, and a dummy transistor that may not be actually operated may be formed on the insulation pattern 134a.

As illustrated above, the fin-type transistor may have enlarged impurity regions and a channel region. The semiconductor device may include the fin-type transistor having uniform electrical characteristics. Also, the planarization process of the gate electrode layer may be skipped so that processes of forming the fin-type transistor may be simplified.

FIGS. 40 to 49 are perspective views and cross-sectional views illustrating stages of a method of manufacturing a semiconductor device in accordance with still other example embodiments.

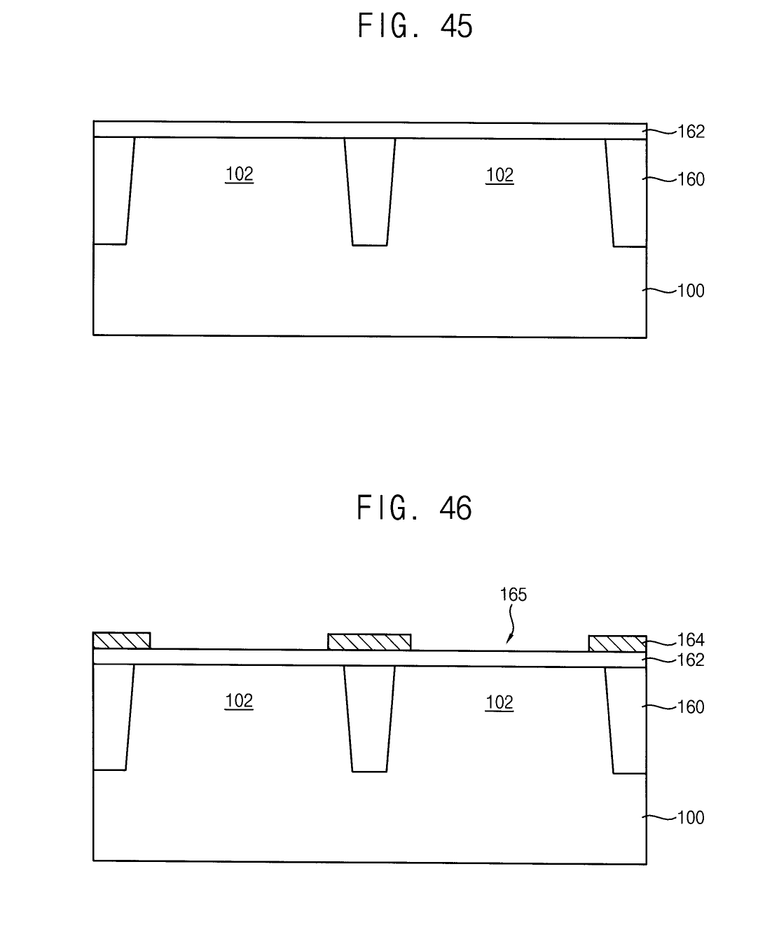

FIGS. 45 to 49 show cross-sectional views taken along a line I-I′ of FIGS. 40 to 44.

Referring to FIGS. 40 and 45, an upper portion of the substrate 100 may be partially etched to form active fins 102 and trench (not shown) therebetween. A preliminary isolation layer 160 may be formed on the substrate 100 to fill the trench. An insulation layer 162 may be formed on the preliminary isolation layer 160 and the active fins 102.

Each of the active fins 102 may extend to a given length in a first direction, and the active fins 102 may be spaced apart from one another in the first direction. Also, the active fins 102 may be arranged to be spaced apart from one another in a second direction substantially perpendicular to the first direction.

An insulation layer may be formed on the substrate 100 to sufficiently fill the trench, and may be planarized until top surfaces of the active fins 102 may be exposed to form the preliminary isolation layer 160.

An insulation layer 162 may be formed on the preliminary isolation layer 160 and the active fins 102. The insulation layer 162 may include a material substantially the same as that of the preliminary isolation layer 160. In some example embodiments, the preliminary isolation layer 160 may be planarized so that a top surface of the active fins 102 may not be exposed, and thus the insulation layer 162 may not be formed.

In other example embodiments, the insulation layer 162 may not be formed to simplify the process so that the active fins 102 may be exposed.

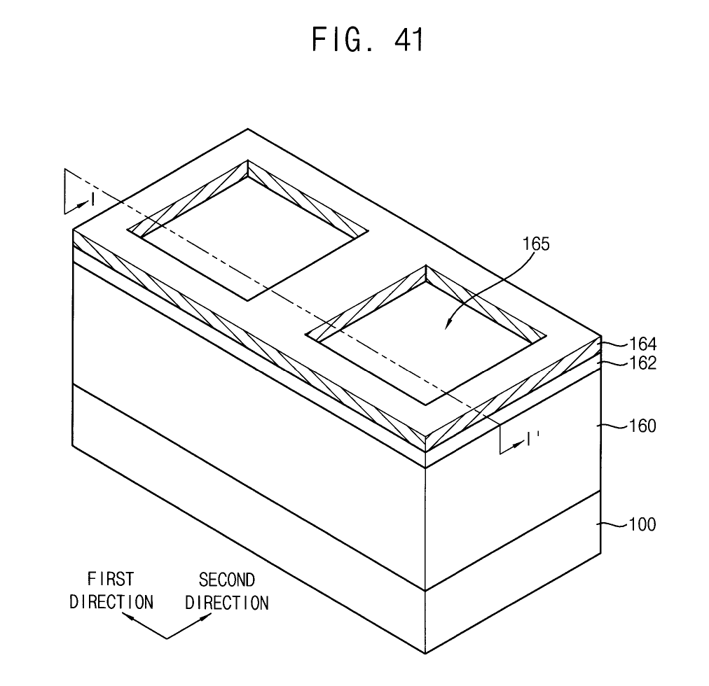

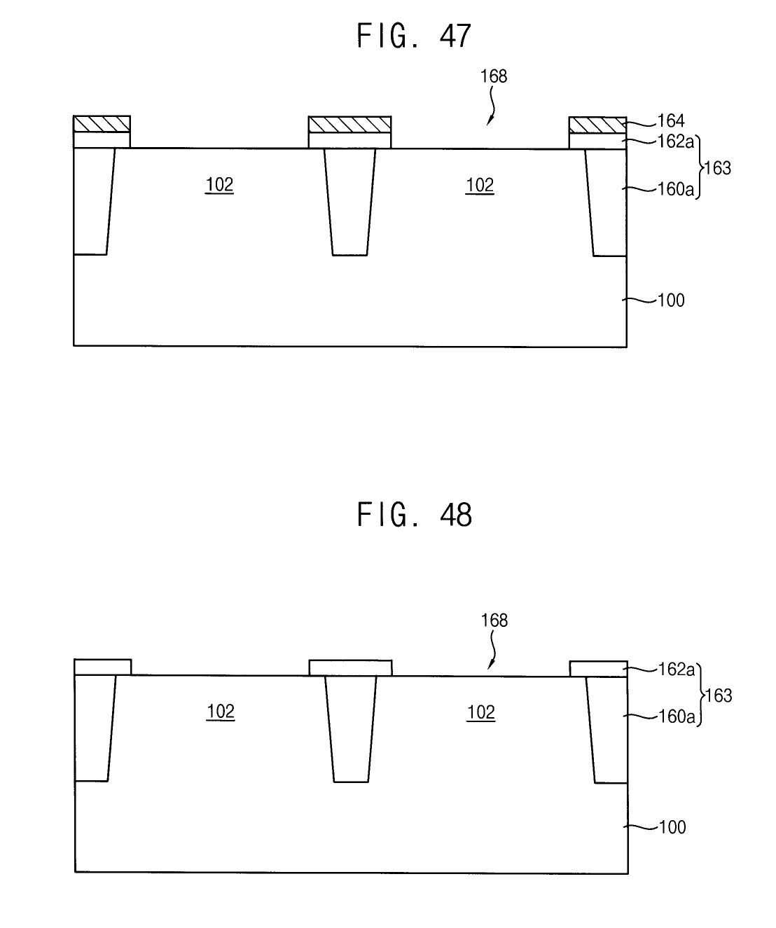

Referring to FIGS. 41 and 46, a hard mask 164 may be formed on the insulation layer 162.

The hard mask 164 may include a first opening 165 in which a first region for forming a fin-type transistor may be exposed. A plurality of first openings 165 may be formed to have an island shape from one another, and a top surface of the hard mask 164 may have a grid shape.

For example, a hard mask layer may be formed on the insulation layer 162. The hard mask layer may serve as an etching mask for etching the insulation layer 162 and the preliminary isolation layer 160. Thus, the hard mask layer may include a material having a high etching selectivity with respect to the insulation layer 162 and the preliminary isolation layer 160. Also, the hard mask layer may include a material having a high etching selectivity with respect to the active fins 102. In example embodiments, the hard mask layer may include, e.g., silicon nitride or silicon oxynitride. The hard mask layer may be patterned by a photolithography process to form the hard mask 164.

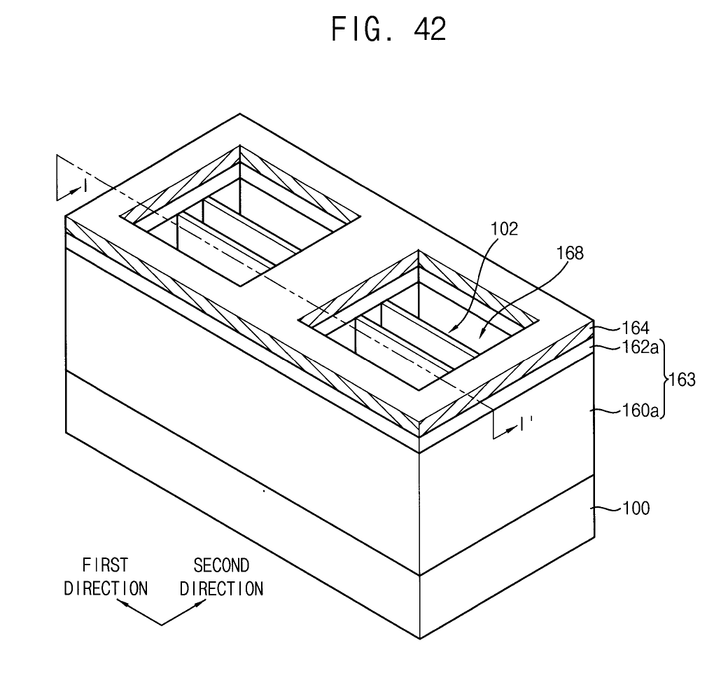

Referring to FIGS. 42 and 47, the insulation layer 162 and the preliminary isolation layer 160 may be etched using the hard mask 164 as an etching mask to form an isolation pattern 160a and an insulation pattern 162a sequentially stacked. A structure 163 including the isolation pattern 160a and the insulation pattern 162a may include a second opening 168.

A bottom of the second opening 168 may expose the isolation pattern 160a, and the active fins 102 may protrude from the upper surface of the isolation pattern 160a. A region of the substrate 100 in which a first portion of the structure 163 between the active fins 102 in the first direction may be a region for forming a dummy transistor. A region of the substrate 100 in which the active fins 102 and second portions of the structure 163 adjacent thereto in the second direction may be a region for forming a fin-type transistor.

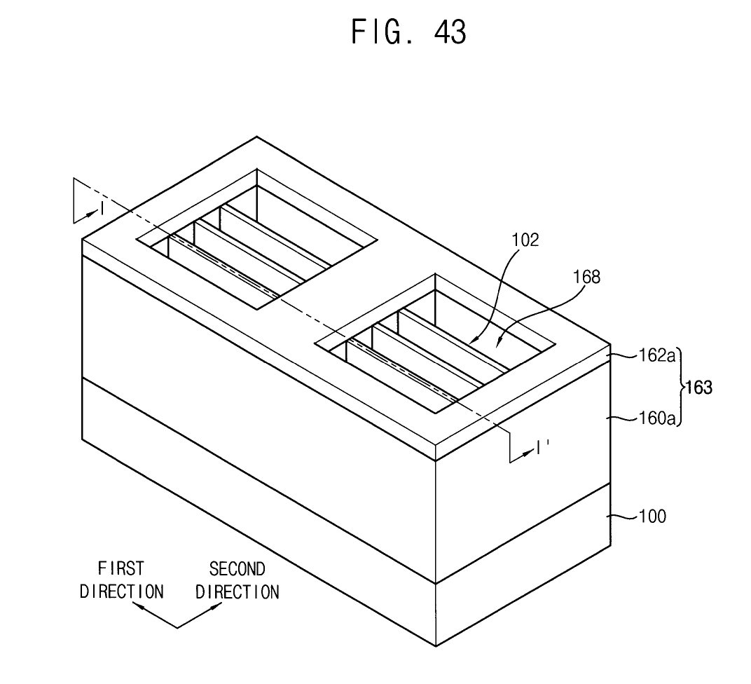

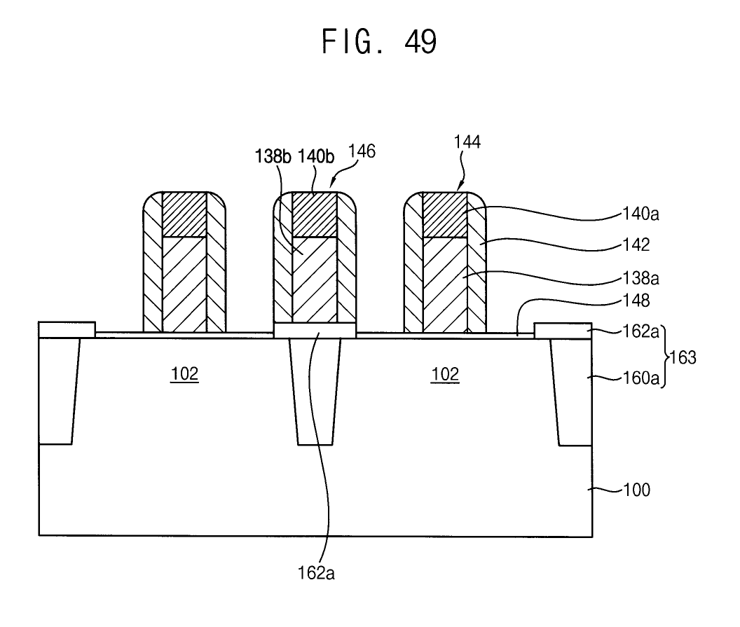

Referring to FIGS. 43 and 48, the hard mask 164 may be removed, and thus an upper surface of the structure 163 may be exposed.

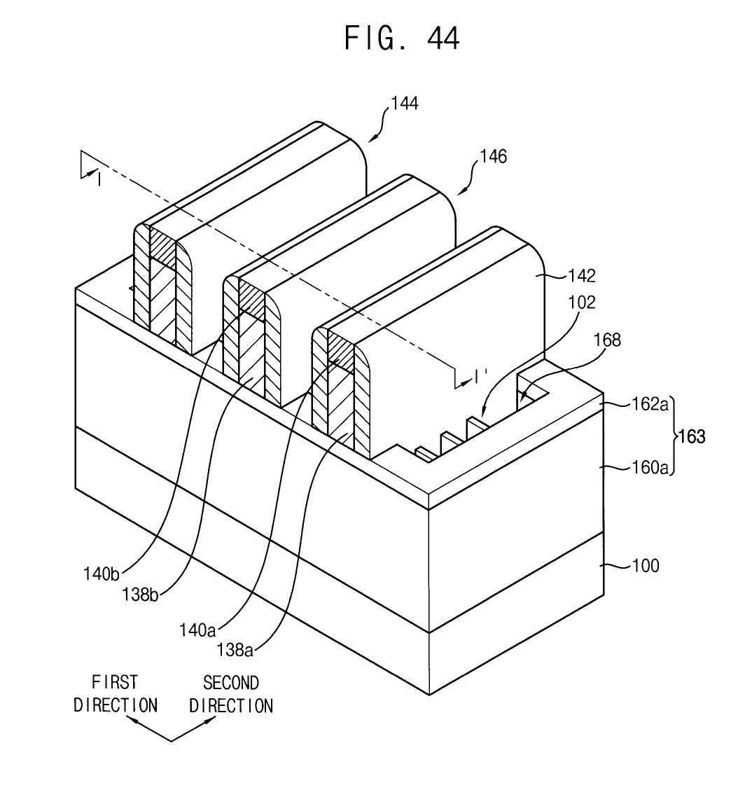

Referring to FIGS. 44 and 49, a gate structure 144 extending in the second direction may be formed on the active fins 102, and a dummy gate structure 146 extending in the second direction may be formed on the insulation pattern 162a.

The gate structure 144 may be formed on the second portion of the insulation pattern 162a that may be parallel to the active fins 102, and in the second opening 168.

The gate structure 144 and the dummy gate structure 146 may be formed by a process substantially the same as or similar to that illustrated in FIG. 36.

A gate insulation layer 148 may be formed on the active fins 102. A gate electrode layer (not shown) may be formed on the gate insulation layer 148 to fill the second opening 168 and to cover the active fins 102. A plurality of second openings 168 may be formed to have an island shape from one another, and a top surface of the structure 163 may be substantially flat. A space between the active fins 102 in the second opening 168 may be small. Thus, a top surface of the gate electrode layer may be substantially flat, and a planarization process of the gate electrode layer may be skipped to simplify the process.

First and second hard masks 140a and 140b may be formed on the gate electrode layer. The gate electrode layer may be etched using the first and second hard masks 140a and 140b as etching masks to form a first gate electrode 138a and a second gate electrode 138b, respectively. A gate structure 144 including the gate insulation layer 148, the first gate electrode 138a and the first hard mask 140a sequentially stacked may be formed on the active fins 102 and the structure 163. Also, a dummy gate structure 146 including the second gate electrode 138b and the second hard mask 140b sequentially stacked may be formed on the structure 163.

A spacer 142 may be formed on the sidewalls of the gate structure 144 and the dummy gate structure 146. Impurities may be doped into the active fins 102 between the gate structure 144 and the dummy gate structure 146 to form impurity regions (not shown).

As illustrated above, a planarization process of the gate electrode layer may be skipped so that processes for forming the fin-type transistor may be simplified.

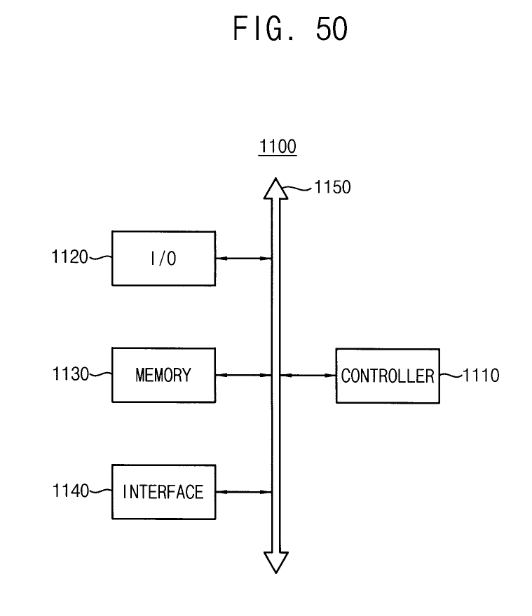

FIG. 50 is a block diagram illustrating an electric system including a semiconductor device in accordance with example embodiments.

Referring to FIG. 50, an electric system 1100 may include a controller 1110, an input/output device 1120, a memory device 1130, an interface 1140, and a bus 1150. The controller 1110, the input/output device 1120, the memory device 1130 and the interface 1140 may be electrically connected to one another via the bus 1140. The bus 1140 may be a path of data. The controller 1110 may include at least one of a microprocessor, a digital signal processor and a logic device. The input/output device 1120 may include, e.g., a keyboard, a keypad, a display monitor, etc. The memory device 1130 may store, e.g., a data and/or a commander, etc. The interface 1140 may receive the data from a communication network or send the data to the communication network. The interface 1140 may have a wired or wireless form. The interface 1140 may include, e.g., an antenna, a wired or wireless transceiver, etc. The electric system 1110 may further include a memory device (not shown) for operation of the controller, and the memory device may include, e.g., a dynamic random access memory (DRAM), a static random access memory (SRAM), etc.

The fin-type transistor in accordance with example embodiments may be applied to the memory device 1130, the controller 1110, the input/output device 1120, etc. The electric system 1110 may be applied to, e.g., personal digital assistants (PDAs), a wireless phone, a digital music player, a memory card or an electric device for a wireless communication, etc.

The above semiconductor device and the method of manufacturing the semiconductor device may be applied to various types of memory devices and system including a MOS transistor.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the inventive concept. Accordingly, all such modifications are intended to be included within the scope of the inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of manufacturing a semiconductor device, the method comprising:
etching a substrate to form a plurality of active fins spaced apart from one another in a first direction, each active fin extending in the first direction;
forming an isolation pattern on the substrate to partially fill a space between the active fins so that the active fins protrude from an upper surface of the isolation pattern;
forming a mold pattern on the isolation pattern, the mold pattern covering at least a portion of each of the active fins and comprising a first opening exposing a portion of the isolation pattern between the active fins in the first direction;
forming an insulation pattern to fill the first opening;
removing the mold pattern to form a second opening exposing the active fins; and
forming a gate structure and a dummy gate structure on the exposed active fins and the insulation pattern, respectively, both of the gate structure and the dummy gate structure extending in a second direction substantially perpendicular to the first direction.

2. The method of claim 1, wherein the forming the mold pattern is performed such that the first opening is formed to have a sidewall of which a slope is in range of about 80° to about 90°, and
wherein a difference between a maximum width in the first direction of the first opening and a minimum width in the first direction of the first opening is less than about 20% of the maximum width thereof.

3. The method of claim 1, wherein the insulation pattern is formed such that a difference between a maximum slope of a sidewall of the insulation pattern and a minimum slope of the sidewall thereof is less than about 20% of the maximum slope thereof.

4. The method of claim 1, wherein the first opening is formed to extend in the second direction.

5. The method of claim 4, wherein the gate structure is formed on the isolation pattern and the active fins.

6. The method of claim 1, wherein the first opening is formed to extend both in the first and second directions, and
wherein the mold pattern structure is formed to have a plurality of mold patterns having an island shape from one another.

7. The method of claim 6, wherein the insulation pattern is formed to include a first portion extending in the first direction and a second portion extending in the second direction, and
wherein the gate structure is formed on the isolation pattern, the first portion of the insulation pattern and the active fins.

8. The method of claim 1, wherein the mold pattern structure include a material having a high etching selectivity with respect to the active fins.

9. The method of claim 1, wherein forming the mold pattern structure includes:
forming a first mold layer to cover the active fins;
forming a second mold layer on the first mold layer;
patterning the second mold layer to form a second mold pattern not overlapping a portion of the isolation pattern between the active fins in the first direction; and
etching the first mold layer using the second mold pattern as an etching mask to form the mold pattern structure including a first mold pattern and the second mold pattern sequentially stacked.

10. The method of claim 9, wherein the first mold layer include polysilicon, and the second mold layer include silicon nitride or silicon oxynitride.

11. The method of claim 1, further comprising:
partially etching an upper portion of the insulation pattern to control a height of the insulation pattern.

12. The method of claim 11, wherein the upper portion of the insulation pattern is partially etched so that an upper surface of the insulation pattern is substantially coplanar with or higher than a top surface of each of the active fins.

13. A method of manufacturing a semiconductor device, the method comprising:
forming a plurality of active fins on a substrate layer to be spaced apart from one another in an active fin direction;
forming an insulation pattern to fill an opening between the active fins such that a length of a bottom surface of the insulation pattern facing the substrate layer is substantially equal to a length of the insulation pattern at a height substantially the same as upper surfaces of the active fins, in the active fin direction; and
forming a gate structure and a dummy gate structure on the active fins and the insulation pattern, respectively.

14. The method of claim 13, wherein the forming the insulation pattern is performed by a damascene process so that a sidewall of the insulation pattern has a substantially vertical slope with respect to an upper surface of the substrate layer.

15. The method of claim 13, wherein the substrate layer comprises a substrate and an isolation pattern formed on the substrate, and
wherein the insulation pattern is formed on the isolation pattern.

16. The method of claim 13, further comprising forming two or more active fins on the substrate to be spaced apart from one another in a direction perpendicular to the active fin direction.

17. The method of claim 13, wherein the forming the gate structure comprises forming at least one drain region and at least one source region on the active fins at one side and another side of the gate structure, respectively.

18. A method of manufacturing a semiconductor device, the method comprising:
providing a substrate having active fins thereon, the active fins being spaced apart from one another in a first direction and a second direction substantially perpendicular to the first direction, and each of the active fins extending in the first direction;
forming an isolation pattern on the substrate, the isolation pattern partially filling a space between the active fins;
forming an insulation pattern on the isolation pattern, the insulation pattern enclosing the active fins and comprising a first portion filling a space between the active fins in the first direction and extending in the second direction and a second portion extending in the second direction to be connected to the first portion;
forming a gate structure on the active fins and the second portion of the insulating pattern, the gate structure extending in the second direction; and
forming a dummy gate structure on the first portion of the insulation pattern, the dummy gate structure extending in the second direction.

19. The semiconductor device of claim 13, wherein the forming the insulation pattern is performed such that a difference between a maximum slope of a sidewall of the insulation pattern and a minimum slope of the sidewall of the insulation pattern is less than about 20% of the maximum slope thereof.

20. The semiconductor device of claim 13, wherein bottom surfaces of both of the gate structure and dummy gate structure are coplanar on the insulation pattern.
